(19) United States
(12) Patent Application Publication
(10) Pub. No.: US 2023/0307426 A1
(43) Pub. Date: Sep. 28, 2023

(54) DISPLAY PANEL, PREPARING METHOD THEREOF, AND DISPLAY DEVICE

(71) Applicant: Tianma Advanced Display Technology Institute (Xiamen) Co., Ltd., Xiamen (CN)

(72) Inventors: Xiaoli LIU, Xiamen (CN); Cao LIU, Xiamen (CN)

(73) Assignee: Tianma Advanced Display Technology Institute (Xiamen) Co., Ltd., Xiamen (CN)

(21) Appl. No.: 18/205,774

(22) Filed: Jun. 5, 2023

(30) Foreign Application Priority Data
Dec. 30, 2022 (CN) 202211740543.8

(51) Int. Cl. H01L 25/075; G09G 3/32; H01L 33/50; H01L 33/58; H01L 33/60; H01L 33/62

(52) U.S. Cl. CPC H01L 25/0753; G09G 3/32; H01L 33/50; H01L 33/58; H01L 33/60; H01L 33/62; G09G 2300/0842; G09G 2300/0408; H01L 2933/0058; H01L 2933/0066

(57) ABSTRACT

Provided are a display panel, a method for preparing a display panel, and a display device. The display panel includes a substrate; multiple driver circuits located on one side of the substrate, where a driver circuit includes a thin-film transistor; multiple light-emitting elements located on the side of the multiple driver circuits facing away from the substrate, where at least one of the multiple light-emitting elements are electrically connected to the multiple driver circuits; and a light-shielding structure, where at least part of light-shielding structure is at least located between a light-emitting element and the thin-film transistor, and the light-shielding structure covers at least an active layer of the thin-film transistor in the direction perpendicular to the plane in which the substrate is located.

### CROSS-REFERENCE TO RELATED APPLICATION(S)

This application claims priority to Chinese Patent Application No. 202211740543.8 filed Dec. 30, 2022, the disclosure of which is incorporated herein by reference in its entirety.

### TECHNICAL FIELD

The present invention relates to the field of display technology and, in particular, to a display panel, a method for preparing a display panel, and a display device.

### BACKGROUND

With the development of science and technology, more and more electronic devices with a display function are widely applied to and bring great convenience for people's daily life and work. Such devices have now become indispensable and important tools for people.

In the field of active matrix display, a thin-film transistor, as a switch for pixels, plays an irreplaceable role. High-resolution and large-size display has become a new direction for the development of display technology. Therefore, higher requirements are put forward for the thin-film transistor. However, the active layer of the thin-film transistor is sensitive to light, and the activity of carriers in the active layer is easily affected by the light. Thus, the thin-film transistor cannot accurately provide a corresponding signal, thereby affecting the light-emitting accuracy of the display panel, and then affecting the display effect of the display panel.

### SUMMARY

The present invention provides a display panel, a method for preparing the display panel, and a display device to improve the light-emitting accuracy of a light-emitting element, thereby improving the display effect of the display panel.

According to one aspect of the present invention, a display panel is provided. The display panel includes a substrate; a plurality of driver circuits located on one side of the substrate, where the plurality of driver circuits include a thin-film transistor; a plurality of light-emitting elements located on the side of the plurality of driver circuits facing away from the substrate, where at least one of the plurality of light-emitting elements are electrically connected to the plurality of driver circuits; and a light-shielding structure, where at least part of the light-shielding structure is at least located between a light-emitting element and the thin-film transistor, and the light-shielding structure covers at least an active layer of the thin-film transistor in the direction perpendicular to the plane in which the substrate is located.

According to another aspect of the present invention, a method for preparing a display panel is provided. The method includes providing a substrate; forming a driver circuit on one side of the substrate, where the driver circuit includes a thin-film transistor; disposing a light-emitting element on one side of the driver circuit, where the light-emitting element is electrically connected to the driver circuit; and forming a light-shielding structure at least between the thin-film transistor and the light-emitting element.

According to another aspect of the present invention, a display device is provided. The display device includes the preceding display panel.

### BRIEF DESCRIPTION OF DRAWINGS

To illustrate technical solutions in embodiments of the present invention more clearly, drawings used in description of the embodiments are briefly described below. Apparently, the drawings described below merely illustrate part of the embodiments of the present invention, and those of ordinary skill in the art may obtain other drawings based on the drawings on the premise that no creative work is done.

FIG. 1 is a diagram illustrating the structure of a film layer of a display panel in the related art.

FIG. 2 is a diagram illustrating the structure of a film layer of a display panel according to an embodiment of the present invention.

FIG. 3 is a diagram illustrating the structure of a driver circuit according to an embodiment of the present invention.

FIG. 4 is a diagram illustrating the structure of a film layer of another display panel according to an embodiment of the present invention.

FIG. 5 is flowchart of a method for preparing a display panel according to an embodiment of the present invention.

FIG. 6 is diagram illustrating the process for preparing a display panel according to an embodiment of the present invention.

FIG. 7 is a diagram illustrating the structure of a film layer of another display panel according to an embodiment of the present invention.

FIG. 8 is a diagram illustrating the structure of a film layer of another display panel according to an embodiment of the present invention.

FIG. 9 is a diagram illustrating the structure of a film layer of another display panel according to an embodiment of the present invention.

FIG. 10 is a diagram illustrating the structure of a film layer of another display panel according to an embodiment of the present invention.

FIG. 11 is a flowchart of a method for preparing a light-shielding structure according to an embodiment of the present invention.

FIG. 12 is a diagram of a process for preparing a light-shielding structure according to an embodiment of the present invention.

FIG. 13 is a diagram illustrating the structure of a film layer of another display panel according to an embodiment of the present invention.

FIG. 14 is a diagram illustrating the structure of a film layer of another display panel according to an embodiment of the present invention.

FIG. 15 is a diagram illustrating the structure of a film layer of another display panel according to an embodiment of the present invention.

FIG. 16 is a diagram illustrating the structure of a film layer of another display panel according to an embodiment of the present invention.

FIG. 17 is a diagram illustrating the structure of a film layer of another display panel according to an embodiment of the present invention.

FIG. 18 is a diagram illustrating the structure of a film layer of another display panel according to an embodiment of the present invention.

FIG. 19 is a diagram illustrating the structure of a film layer of another display panel according to an embodiment of the present invention.

FIG. 20 is a diagram illustrating the structure of a film layer of another display panel according to an embodiment of the present invention.

FIG. 21 is a diagram illustrating the structure of a film layer of another display panel according to an embodiment of the present invention.

FIG. 22 is a top diagram illustrating the structure of a display panel according to an embodiment of the present invention.

FIG. 23 is a diagram illustrating the structure of a film layer of another display panel according to an embodiment of the present invention.

FIG. 24 is a diagram illustrating the structure of a film layer of another display panel according to an embodiment of the present invention.

FIG. 25 is a diagram illustrating the structure of a film layer of another display panel according to an embodiment of the present invention.

FIG. 26 is a top diagram illustrating the structure of another display panel according to an embodiment of the present invention.

FIG. 27 is a section structure diagram taken along section A-A′ in FIG. 26.

FIG. 28 is another section structure diagram taken along section A-A′ in FIG. 26.

FIG. 29 is a flowchart of a method for preparing a transparent structure according to an embodiment of the present invention.

FIG. 30 is a diagram of a process for preparing a transparent structure according to an embodiment of the present invention.

FIG. 31 is a flowchart of another method for preparing a transparent structure according to an embodiment of the present invention.

FIG. 32 is a diagram of another process for preparing a transparent structure according to an embodiment of the present invention.

FIG. 33 is a section structure diagram of another display panel according to an embodiment of the present invention.

FIG. 34 is a section structure diagram taken along section B-B′ in FIG. 26.

FIG. 35 is a top diagram illustrating the structure of another display panel according to an embodiment of the present invention.

FIG. 36 is a section structure diagram taken along section C-C′ in FIG. 35.

FIG. 37 is a section structure diagram of another display panel according to an embodiment of the present invention.

FIG. 38 is a section structure diagram of another display panel according to an embodiment of the present invention.

FIG. 39 is a diagram illustrating the structure of a display device according to an embodiment of the present invention.

### DETAILED DESCRIPTION

The technical solutions in the embodiments of the present invention are described clearly and completely in conjunction with the drawings in the embodiments of the present invention from which the solutions of the present invention are better understood by those skilled in the art. Apparently, the embodiments described below are part, not all, of the embodiments of the present invention. Based on the embodiments of the present invention, all other embodiments obtained by those of ordinary skill in the art on the premise that no creative work is done are within the scope of the present invention.

It is to be noted that the terms “first”, “second”, and the like in the description, claims, and drawings of the present invention are used for distinguishing between similar objects and are not necessarily used for describing a particular order or sequence. It is to be understood that the data used in this way is interchangeable where appropriate so that the embodiments of the present invention described herein may also be implemented in a sequence not illustrated or described herein. In addition, the terms “including”, “having”, or any other variations thereof described herein are intended to encompass a non-exclusive inclusion. For example, a process, method, system, product, or device that includes a series of steps or units may include not only the expressly listed steps or units but also other steps or units that are not expressly listed or are inherent to such a process, method, system, product, or device.

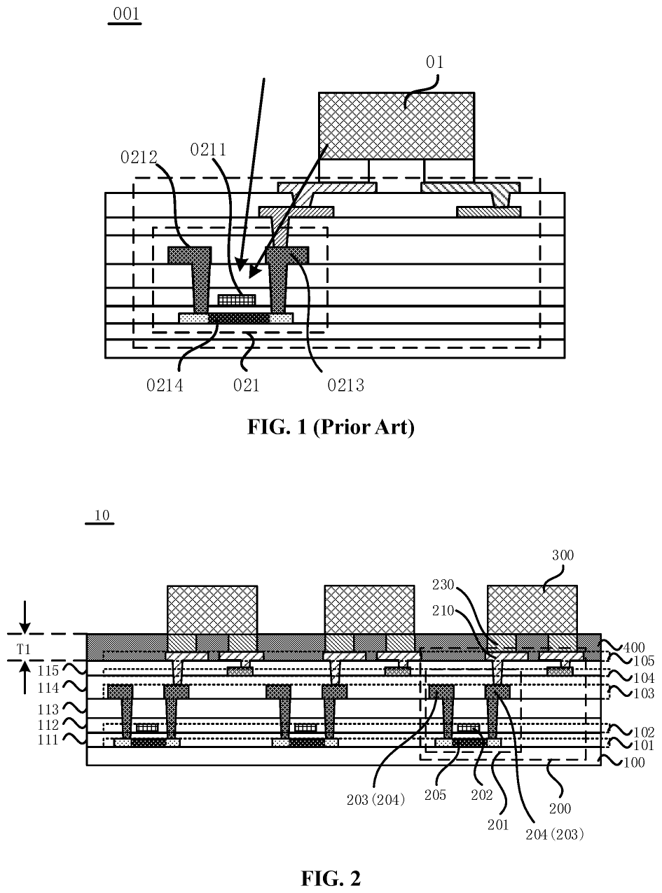

As described in the background, the activity of carriers in the active layer in the thin-film transistor in a display panel is easily affected by the light. FIG. 1 is a diagram illustrating the structure of a film layer of a display panel in the related art. Referring to FIG. 1, a light-emitting element 01 in a display panel 001 in the related art is provided with an electric signal by a driver circuit 02 to implement display light emission. The driver circuit 02 includes a thin-film transistor 021. The thin-film transistor 021 includes a gate 0211, a source 0212, a drain 0213, and an active layer 0214. The thin-film transistor 021 can control carriers in the active layer 0214 according to the control signal received by the gate 0211 of the thin-film transistor 021, thereby controlling the magnitude of the channel current in the thin-film transistor 021 to provide a corresponding electric signal for the light-emitting element 01 to implement control of display light emission of the light-emitting element 01. However, the activity of carriers in the active layer 0214 is easily affected by the light. When the active layer 0214 is irradiated with the light emitted from the external ambient light or the light-emitting element 01, the carriers in the active layer 0214 change. Thus, the channel current changes, thereby affecting the magnitude of the electric signal provided by the driver circuit 02 to the light-emitting element 01, so the light-emitting element 01 cannot emit light accurately, thereby affecting the display effect of the display panel 001.

In addition, with the development of technology, the number of pixels per unit area in a display panel is increasing. For a high-resolution display panel, the traditional technology of defining light-emitting elements in a pixel defining layer needs to use the opening technique and mask technologies, so it is difficult to implement too many and too small openings. Therefore, this arrangement manner is not advantageous to the high resolution of the display panel. The LED mass transfer technology can implement the high resolution of a display panel. However, based on the requirements of the LED bonding technique, a certain space needs to be reserved around the light-emitting element 01. This results light entering from this space and propagating to the active layer 0214 of the thin-film transistor 021. Especially when the light-emitting element 01 is in a highlight state, the leakage current of the thin-film transistor 021 is more serious, and even the brightness of high-profile light (100%) is lower than that of low-profile light (20%).

To solve the preceding technical problems, the embodiments of the present invention provide a display panel. The display panel includes a substrate; multiple driver circuits located on one side of the substrate, where a driver circuit includes a thin-film transistor; multiple light-emitting elements located on the side of the multiple driver circuits facing away from the substrate, where the multiple light-emitting elements are electrically connected to the multiple driver circuits; and a light-shielding structure located at least between a light-emitting element and the thin-film transistor, where the light-shielding structure covers at least an active layer of the thin-film transistor in the direction perpendicular to the plane in which the substrate is located.

According to the preceding technical solutions, the light-shielding structure is disposed at least between the light-emitting element and the thin-film transistor. Thus, the light emitted from the light-emitting element and/or at least part of the light propagating to the side of the thin-film transistor in the external ambient light can be blocked from propagating to the position in which the active layer of the thin-film transistor is located, thereby improving the influence caused by the light on the channel carrier of the thin-film transistor. Moreover, the driver circuit including the thin-film transistor can accurately provide a drive signal for the light-emitting element, thereby improving the light-emitting accuracy of the light-emitting element driven by the driver circuit, and improving the display effect of the display panel. Further, the light-blocking structure is disposed between at least the thin-film transistor and the light-emitting element to block at least part of light emitted from the light-emitting element and/or external ambient light. Thus, the part of the light can be prevented from reaching the driver circuit and being reflected by the metal structure or the like in the thin-film transistor, thereby reducing unnecessary reflection in the display panel and improving the display brightness and the display contrast.

The preceding is the core idea of the present invention. Based on the embodiments of the present invention, all other embodiments obtained by those of ordinary skill in the art are within the scope of the present invention on the premise that no creative work is done. Technical solutions in the embodiments of the present invention are described clearly and completely hereinafter in conjunction with the drawings in the embodiments of the present invention.

FIG. 2 is a diagram illustrating the structure of a film layer of a display panel according to an embodiment of the present invention. Referring to FIG. 2, a display panel 10 includes a substrate 100; multiple driver circuits 200, where a driver circuit 200 includes a thin-film transistor 201; multiple light-emitting elements 300 located on the side of the multiple driver circuits 200 facing away from the substrate 100, where the multiple light-emitting elements 300 are electrically connected to the multiple driver circuits 200; and a light-shielding structure 400 located at least between a light-emitting element 300 and a thin-film transistor 201, where the light-shielding structure 400 at least covers the active layer 205 of the thin-film transistor 201 in the direction perpendicular to the plane in which the substrate 100 is located.

It is to be noted that a thin-film transistor 201 may include an active layer 205, a gate 202, a source 203, and a drain 204. The active layer 205 may include a source region, a drain region, and a channel region located between the source region and the drain region. In the direction perpendicular to the plane in which the substrate 100 is located, the gate 202 generally covers the channel region of the active layer 205. The source 203 is electrically connected to the source region by a via. The drain 204 is electrically connected to the drain region by the via. By applying a corresponding electrical signal to the gate 202, the activity of carriers in the channel region in the active layer 205 can be controlled to control the on-off of the source 203 electrically connected to the source region and the drain 204 electrically connected to the drain region. The thin-film transistor 201 may be a device directly or indirectly electrically connected to a light-emitting element 300. Exemplarily, the thin-film transistor 201 is a device indirectly electrically connected to the light-emitting element 300. The display panel 10 may also include a lap join structure 210 and a bonding electrode 230. The source 203 or drain 204 of the thin-film transistor 201 is electrically connected to the light-emitting element 300 via the lap join structure 210 and the bonding electrode 230 in turn.

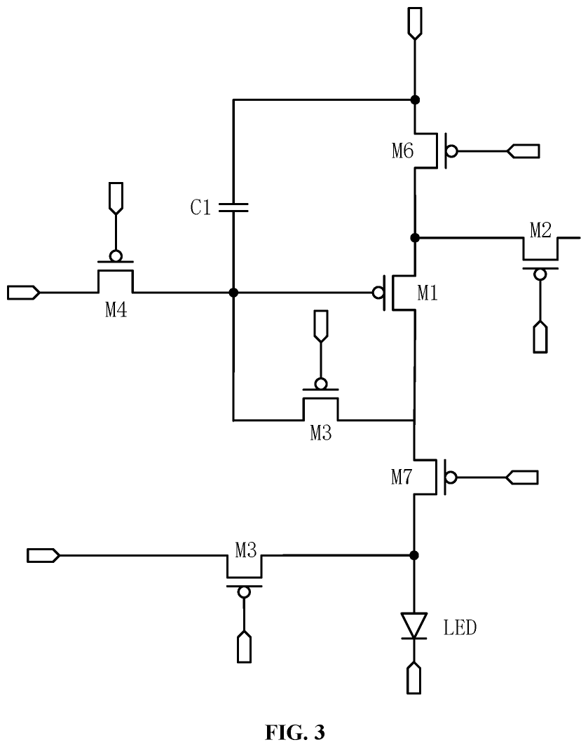

It is also to be noted that in addition to including the thin-film transistor 201, the driver circuit 200 may also include other active and/or passive devices. For example, the active device may be a device including three or four terminals, such as a control terminal, an input terminal, and an output terminal. The passive device may be a two-terminal device, such as a capacitor, a resistor, or an inductor. In an example embodiment, as shown in FIG. 3, the driver circuit may be a 7T1C driver circuit. In this case, the driver circuit may include an initialization transistor M4, a threshold compensation transistor M3, a data write transistor M2, a first light emission control transistor M6, a second light emission control transistor M7, a reset transistor M3, a drive transistor M1, and a storage capacitor C1. The specific working principle of driver circuit is similar to a 7T1C driver circuit typical in the related art, and details are not described herein.

It is to be understood that the light-emitting element 300 may be, for example, a submillimeter light-emitting diode (Mini LED) or a micro light-emitting diode (Micro LED). The type of the light-emitting element 300 is not specifically limited in this embodiment. The multiple light-emitting elements 300 may each be a blue light-emitting element or a white light-emitting element for emitting blue light or white light. Alternatively, the multiple light-emitting elements 300 may also include light-emitting elements emitting light of different colors, for example, include a red light-emitting element, a green light-emitting element, and a blue light-emitting element. The red light-emitting element can emit red light. The green light-emitting element can emit green light. The blue light-emitting element can emit blue light. The light of different colors is combined with each other to enable the display panel to implement color display.

It is also to be understood that the substrate 100 may be transparent, translucent, or opaque. The substrate 100 may be a rigid substrate, such as a glass substrate or a silicon substrate. The substrate 100 may also be a flexible substrate, for example, a flexible resin-based material, or formed of a polymer with a thinner thickness. Specific materials may include polyimide (PI), polyethylene terephthalate (PET), polyethylene naphthalate (PEN), and the like.

In addition, with continued reference to FIG. 2, the light-shielding structure 400 is also disposed between a driver circuit 200 and a light-emitting element 300. The light-shielding structure 400 is a structure having a larger light-blocking capability or a smaller light transmission capability. The light-shielding structure 400 may include a black photoresist material. Accordingly, the optical density (OD) value of the light-shielding structure 400 may be greater than or equal to 1.0. Since the optical density value is the logarithm of the ratio of incident light to transmitted light or the logarithm of the reciprocal of light transmittance, the light-shielding structure 400 can have a sufficient light-shielding capability by making the optical density (OD) value ≥1.0.

Specifically, the light emitted from the light-emitting element 300 propagates in all directions. That is, the light emitted from the light-emitting element 300 not only propagates towards the side facing away from the substrate 100, but also part of the light propagates towards the side facing the substrate 100. Therefore, when the light propagating to the side facing the substrate 100 reaches the position in which the thin-film transistor 201 of the driver circuit 200 is located without blocking, the activity of carriers in the active layer 205 in the thin-film transistor 201 is affected. Thus, electric leakage occurs in the thin-film transistor 201, and threshold drift occurs in the thin-film transistor 201, thereby affecting the thin-film transistor 201 to provide a drive signal for the light-emitting element 300. The light-shielding structure 400 is disposed at least between the light-emitting element 300 and the driver circuit 200. That is, the light-shielding structure 400 is located on the side of the light-emitting element 300 facing the thin-film transistor 201. In the direction perpendicular to the plane in which the substrate 100 is located, the light-shielding structure 400 covers at least the active layer 205 of the thin-film transistor 201. Thus, the light-shielding structure 400 can block at least part of light emitted from the light-emitting element 300 and propagating to the side facing the substrate 100 to prevent the part of light from reaching the active layer of the thin-film transistor 201 to influence the activity of carriers in the active layer of the thin-film transistor 201. Moreover, the electric leakage generated by the light can be reduced so that the thin-film transistor 201 can accurately provide a drive signal for the light-emitting element 300, thereby enabling the light-emitting element 300 to emit light accurately. In addition, the light-shielding structure 400 located at least between the light-emitting element 300 and the driver circuit 200 can also block the enter of at least part of external ambient light to effectively reduce the light propagating to the active layer 205 in the thin-film transistor 201. Thus, the electric leakage of the thin-film transistor 201 is reduced in the case where the light-emitting element 300 is highlighted and/or the external ambient light is brighter so that the thin-film transistor 201 can provide an accurate drive signal for the light-emitting element 300, thereby improving the light-emitting accuracy of the light-emitting element 300.

In addition, with continued reference to FIG. 2, the film layer structure of the display panel 10 may include a semiconductor layer 101 and multiple conductive layers (102, 103, 104, and 105) located on one side of the substrate 100, and insulation layers (111, 112, 113, 114, and 115) located between the semiconductor layer 101 and a conductive layer and between conductive layers. The semiconductor layer 101 may include the active layer 205 of the thin-film transistor 201. The conductive layers (102, 103, 104, and 105) may include the gate 202, source 203, drain 204, lap join electrode 210, and bonding electrode 230 of the thin-film transistor 201. The material of conductive layers may include a metal or the like. The metal material generally has a reflective effect. In the embodiments of the present invention, the light-shielding structure 400 is disposed at least between the thin-film transistor 201 and the light-emitting element 300. Thus, the light-shielding structure 400 can block at least part of the light from reaching corresponding conductive layers, thereby reducing reflection of the light by the structure in the conductive layers. Moreover, the case in which the display contrast of the display panel 10 is affected by the presence of more reflected light is improved, thereby effectively improving the display brightness and the display contrast of the display panel.

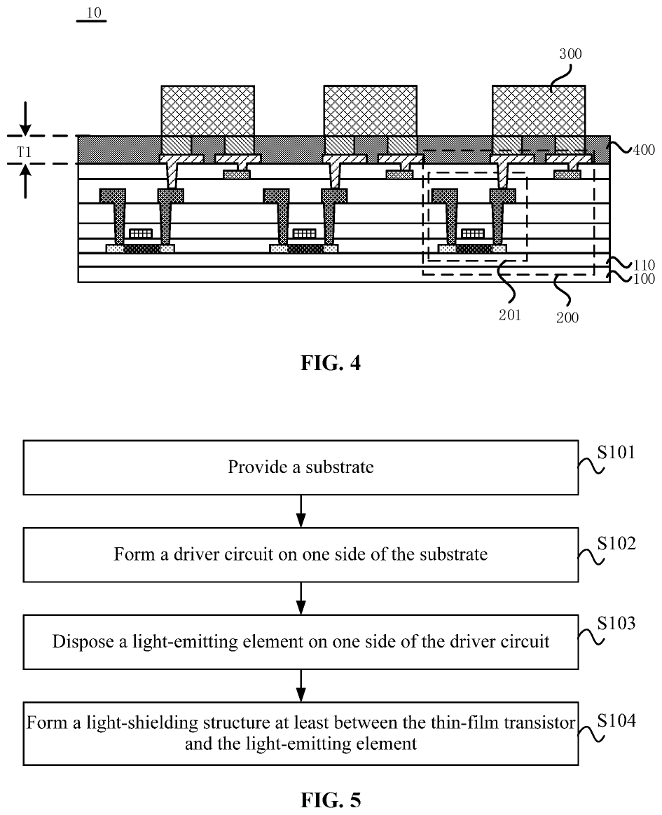

It is to be understood that the preceding description of the film layer structure of the display panel is only for example. The film layer structure of the display panel includes but is not limited to the preceding description. For example, in an optional embodiment, as shown in FIG. 4, the display panel 10 may also include a buffer layer 110 located between the substrate 100 and the semiconductor layer. The buffer layer 110 may include a stacked structure of an inorganic layer and an organic layer to block oxygen and moisture and prevent diffusion of moisture or impurities through the substrate. On the premise that the core invention points of the embodiments of the present invention can be implemented, the film layer structure of the display panel 10 is not specifically limited in the embodiments of the present invention.

According to the embodiments of the present invention, the light-shielding structure is disposed at least between the light-emitting element and the thin-film transistor. Thus, the light emitted from the light-emitting element and/or at least part of the light propagating to the side of the thin-film transistor in the external ambient light can be blocked from propagating to the position in which the active layer of the thin-film transistor is located, thereby improving the influence caused by the light on the channel carrier of the thin-film transistor. Moreover, the driver circuit including the thin-film transistor can accurately provide a drive signal for the light-emitting element, thereby improving the light-emitting accuracy of the light-emitting element driven by the driver circuit, and improving the display effect of the display panel. Further, the light-blocking structure is disposed between at least the thin-film transistor and the light-emitting element to block at least part of light emitted from the light-emitting element and/or external ambient light. Thus, the part of the light can be prevented from reaching the driver circuit and being reflected by the metal structure or the like in the thin-film transistor, thereby reducing unnecessary reflection in the display panel and improving the display brightness and the display contrast.

In the embodiments of the present invention, the light-shielding structure is located at least between the light-emitting element and the thin-film transistor. The light-shielding structure may be disposed before the light-emitting element is disposed. Alternatively, the light-shielding structure may be disposed after the light-emitting element is disposed. This is not specifically limited in the embodiments of the present invention.

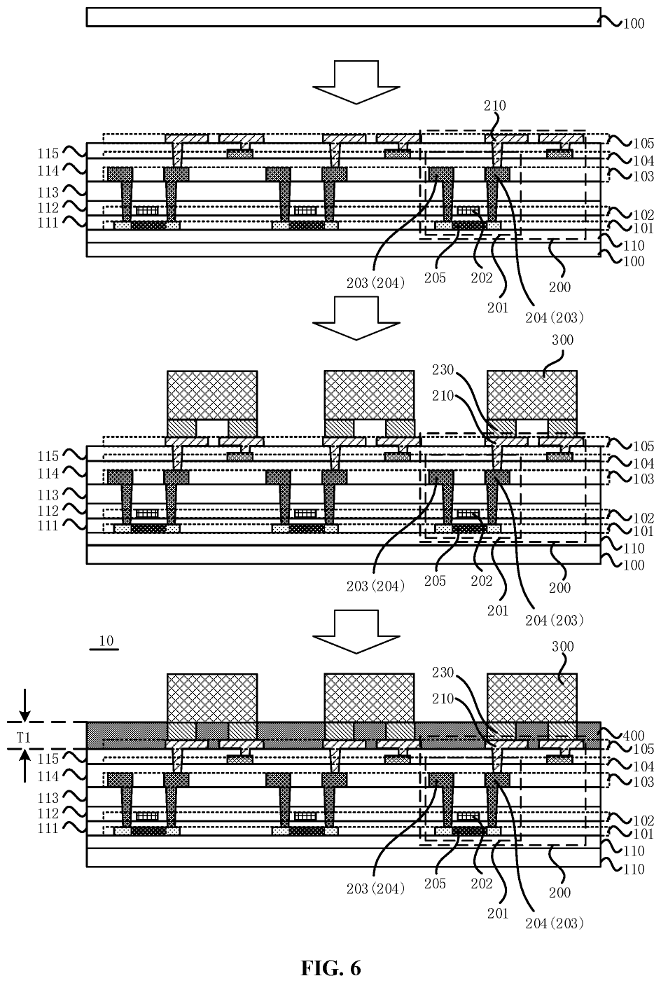

In an embodiment, FIG. 5 is flowchart of a method for preparing a display panel according to an embodiment of the present invention. FIG. 6 is diagram illustrating the process for preparing a display panel according to an embodiment of the present invention. Referring to FIG. 5, the method for preparing a display panel includes the following steps.

In S101, a substrate is provided.

As shown in FIG. 6, the substrate 100 provided may be a rigid substrate or a flexible substrate. The rigid substrate has a certain hardness, such as a glass substrate. The flexible substrate is flexible and deformable, such as a PI substrate.

In S102, a driver circuit is formed on one side of the substrate.

Specifically, with continued reference to FIG. 6, a driver circuit 200 includes a thin-film transistor 201. The specific forming process of the thin-film transistor 201 includes the following: forming a semiconductor layer 101 on one side of the substrate 100 and patterning the semiconductor layer 101 to form an active layer 205 of the thin-film transistor. An interlayer dielectric layer 111 is disposed on the side of the semiconductor layer 101 facing away from the substrate. A first conductive layer 102 is formed on the side of the interlayer dielectric layer 111 facing away from the substrate 100, and the first conductive layer 102 is patterned to form a gate 202 of the thin-film transistor 201. An insulation layer 112 and an insulation layer 113 are disposed on the side of the first conductive layer 102 facing away from the substrate 100, and a via penetrating the insulation layers and the interlayer dielectric layer are formed to expose a source region and a drain region of the active layer 205, respectively. A second conductive layer 103 is formed on the side of the insulation layer 113 facing away from the substrate 100, and the second conductive layer 103 is patterned to form a source 203 electrically connected to the source region by a via and a drain 204 electrically connected to the drain region by the via. The preparation technique of the first conductive layer 102 and the second conductive layer 103 may include, but is not limited to, deposition and sputtering. In addition, the preparation process of the driver circuit 200 may also include the preparation process of other devices, the preparation process of a lap join electrode, and the like. The specific preparation technique of the driver circuit 200 may be similar to the preparation technique of the gate 202, source 203, and drain 204 of the thin-film transistor 201. Details are not described herein.

In S103, a light-emitting element is disposed on one side of the driver circuit.

Specifically, with continued reference to FIG. 6, a light-emitting element 300 is electrically connected to the driver circuit 200. The light-emitting element 300 may be a Mini LED or a Micro LED. In this case, after the light-emitting element 300 is prepared by a preparation process such as epitaxial growth, the light-emitting element is transferred to the side of the driver circuit 200 facing away from the substrate 100 through the mass transfer technique and electrically connected to the driver circuit 200. Mass transfer manners of the light-emitting element 300 include, but are not limited to, an electrostatic force transfer technology, a micro-transfer printing technology, and a self-assembly technology.

In S104, a light-shielding structure is formed at least between the thin-film transistor and the light-emitting element.

Specifically, with continuing reference to FIG. 6, after the light-emitting element 300 is disposed on the side of the driver circuit 200 facing away from the substrate 100, a specific manner of forming the light-shielding structure 400 at least between the light-emitting element 300 and the thin-film transistor 201 of the driver circuit 200 may include filling a material of the light-shielding structure at least between the light-emitting element 300 and the driver circuit 200 by a technique such as coating or printing. The material of the light-shielding structure 400 includes, but is not limited to, a photoresist having a light-shielding effect. Generally, the photoresist has certain fluidity before curing so that the material of the light-shielding structure 400 can sufficiently fill the gap between the light-emitting element 300 and the driver circuit 200. Further, the light-shielding structure 400 can cover at least the active layer 205 of the thin-film transistor 201 in the direction perpendicular to the plane in which the substrate 100 is located. Thus, the light-shielding structure 400 can block light entering the active layer 205 of the thin-film transistor 201. This can improve electric leakage due to light so that the thin-film transistor 201 has good switching characteristics.

In addition, after the light-emitting element 300 is disposed on one side of the driver circuit 200 so that the light-emitting element 300 is electrically connected to the driver circuit 200, the light-shielding structure 400 is formed at least between the thin-film transistor 201 and the light-emitting element 300. An opening for disposing the light-emitting element 300 is not required in the light-shielding structure 400, thereby facilitating the simplification of the technique preparation process of the display panel. At the same time, since an opening for disposing the light-emitting element 300 is not required in the light-shielding structure 400, the resolution of the display panel 10 is not affected by a technique preparation process such as setting the opening. When the light-emitting element 300 is a Mini LED or a Micro LED, the light-emitting element 300 has a smaller size, thereby facilitating the high resolution of the display panel 10.

It is to be understood that the preceding is only exemplary description of the technique preparation process of the display panel in the embodiments of the present invention. On the premise that the core invention points of the embodiments of the present invention can be implemented, the technique preparation process of the display panel is not specifically limited in the embodiments of the present invention.

It is also to be understood that the light-shielding structure is located at least between the thin-film transistor and the light-emitting element in the embodiments of the present invention. That is, the light-shielding structure can fill all the gap between the light-emitting element and the thin-film transistor or can fill part of the gap between the light-emitting element and the thin-film transistor. This is not specifically limited in the embodiments of the present invention. At the same time, materials of the light-shielding structure include, but are not limited to, a photoresist having fluidity. When the materials of the light-shielding structure include a photoresist, the material of the light-shielding structure may include a black photoresist. That is, a black dye is doped into a material such as a photosensitive resin. Thus, the light-shielding structure can have a high light-shielding capability. Alternatively, the light-shielding structure may be a titanium dioxide-doped photoresist. In this case, titanium dioxide particles can be doped into a material such as a photosensitive resin. Thus, the titanium dioxide-doped photoresist has a certain light-shielding capability.

In an optional embodiment, in order that the light-shielding structure 400 has a sufficient light-blocking capability, the value range of the thickness T1 of the light-shielding structure 400 in the direction perpendicular to the plane in which the substrate 100 is located is T1≥1/OD. OD denotes an optical density value of the light-shielding structure 400.

The optical density value is the logarithm of the ratio of incident light to transmitted light or the logarithm of the reciprocal of light transmittance. When the optical density value of the light-shielding structure 400 is larger, the light flux of the light-shielding structure 400 per unit size is smaller. Most of the light can be shielded without superimposing a thick material of the light-shielding structure 400. Therefore, the light-shielding structure 400 can have a smaller thickness T1 in the direction perpendicular to the plane in which the substrate 100 is located. However, when the optical density value of the light-shielding structure 400 is small, the light flux of the light-shielding structure 400 per unit size is larger. A thick material of the light-shielding structure 400 is required to superimpose so that more light can be shielded. Therefore, the light-shielding structure 400 needs to have a larger thickness T1 in the direction perpendicular to the plane in which the substrate 100 is located. Thus, the minimum thickness of the light-shielding structure 400 is defined according to the optical density value of the light-shielding structure 400. This can ensure that the light-shielding structure 400 has a sufficiently large light-shielding capability.

In an optional embodiment, when the value range of the thickness T1 of the light-shielding structure 400 is T1≥1/OD, the thickness of the light-shielding structure 400 is thinned as much as possible to ensure that the light-shielding structure 400 has a sufficiently large light-shielding capability, and the light and thinning of the display panel 10 are facilitated. In this case, the value range of the optical density value of the light-shielding structure 400 is OD≥1.0.

It is to be understood that the optical density (OD) value of the light-shielding structure 400 may be less than 1.0. In this case, the thickness T1 of the light-shielding structure 400 in the direction perpendicular to the plane in which the substrate 100 is located is appropriately increased so that T1≥1/OD can satisfy the light-shielding requirement.

It is to be noted that the preceding only exemplarily uses the case where the light-shielding structure 400 is located between the thin-film transistor 201 and the light-emitting element 300 as an example for the description of the technical solutions in the embodiments of the present invention. The light-shielding structure 400 may be located at other positions in the embodiments of the present invention. The following exemplarily describes the technical solutions in the embodiments of the present invention for typical examples.

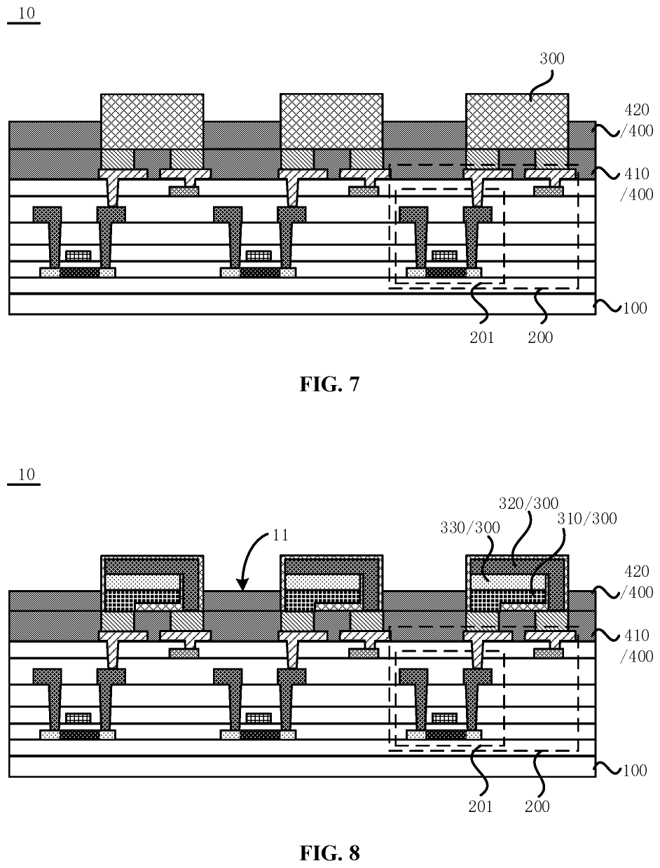

In an embodiment, FIG. 7 is a diagram illustrating the structure of a film layer of another display panel according to an embodiment of the present invention. Referring to FIG. 7, a light-shielding structure 400 includes a first light-shielding portion 410 and a second light-shielding portion 420. The first light-shielding portion 410 is located between light-emitting elements 300 and thin-film transistors 201. The first light-shielding portion 410 overlaps the thin-film transistors 201 in the direction perpendicular to the plane in which a substrate 100 is located. The second light-shielding portion 420 is located on the side of the first light-shielding portion 410 facing away from the substrate 100. The second light-shielding portion 420 is located between two adjacent light-emitting elements 300.

Exemplarily, the first light-shielding portion 410 and the second light-shielding portion 420 may be made of the same material and are prepared and integrally formed in the same process. The first light-shielding portion 410 is located at least between a light-emitting element 300 and a thin-film transistor 201 and can block at least part of the light from propagating to the position in which the active layer 205 of the thin-film transistor 201 is located. The first light-shielding portion 410 can also block at least part of the light from reaching a driver circuit and being reflected by a metal structure or the like in the thin-film transistor 201. The second light-shielding portion 420 is located between two adjacent light-emitting elements 300 and can block at least part of the light emitted from a light-emitting element 300 to the adjacent light-emitting element 300. In this manner, the mutual crosstalk of the light emitted from adjacent light-emitting elements 300 can be reduced, and the contrast ratio of a display panel 10 can be improved.

It is to be noted that patterns filled in figures are used only for distinguishing different film layer structures. Pattern types are not used for distinguishing film layer materials. The same pattern type may be different film layer materials and different film layer structures. The same film layer material may be different filling patterns. The first light-shielding portion 410 and the second light-shielding portion 420 may be of the same material or different materials. This is not specifically limited in the embodiments of the present invention.

In an embodiment, with continued reference to FIG. 7, the surface of the side of the second light-shielding portion 420 facing the light-emitting element 300 is in contact with the surface of the side of the light-emitting element 300 facing the second light-shielding portion 420.

Specifically, the second light-shielding portion 420 may be disposed around the light-emitting element 300 and is in contact with the light-emitting element 300. That is, no gap is disposed between the second light-shielding portion 420 and the light-emitting element 300. Light cannot enter the film layer in which the active layer in the thin-film transistor 201 is located from the gap between two adjacent light-emitting elements 300. In this manner, the light emitted from the light emitting element 300 and/or the external ambient light entering the film layer in which the active layer of the thin film transistor 201 is located can be reduced as much as possible, thereby preventing light from affecting the activity of carriers in the active layer of the thin-film transistor 201, further enabling the thin-film transistor 201 to provide an accurate drive signal for the light-emitting element 300 to accurately drive the light-emitting element 300 to emit light. At the same time, when the light-shielding structure 400 has a high light-shielding capability, light emitted from the light-emitting element 300 and/or the external ambient light cannot pass through the light-shielding structure 400 to the film layer having a reflection function in a driver circuit 200. Thus, light reflection in the display panel can be reduced, further improving the display brightness and display contrast of the display panel.

In an embodiment, FIG. 8 is a diagram illustrating the structure of a film layer of another display panel according to an embodiment of the present invention. Referring to FIG. 8, the surface of the side of a second light-shielding portion 420 facing away from a substrate 100 is a first surface 11. A light-emitting element 300 includes a first electrode 310, a second electrode 320, and a light-emitting layer 330. The first electrode 310 is located on the side of the second electrode 320 facing the substrate 100. The light-emitting layer 330 is located between the first electrode 310 and the second electrode 320. The first surface 11 is flush with the surface of the side of the light-emitting layer 330 facing the substrate 100. Alternatively, the first surface 11 is located on the side of the light-emitting layer 330 facing the substrate 100.

When the distance between the first surface 11 and the substrate 100 is a first distance, and the distance between the surface of the side of the light-emitting layer 330 facing the substrate 100 and the substrate 100 is a second distance, the first surface 11 is flush with the surface of the side of the light-emitting layer 330 facing the substrate 100. It is to be understood that the first distance is equal to the second distance. In this case, the surface height of the first surface 11 is the same as the surface height of the surface of the side of the light-emitting layer 330 facing the substrate 100 with the plane in which the substrate 100 is located as a reference plane. Accordingly, the first surface 11 is located on the side of the light-emitting layer 330 facing the substrate 100. It is to be understood that the first distance is less than the second distance. That is, the surface height of the first surface 11 is less than the surface height of the surface of the side of the light-emitting layer 330 facing the substrate 100 with the plane in which the substrate 100 is located as a reference plane.

According to the embodiments, the surface height of the first surface 11 is less than or equal to the surface height of the surface of the side of the light-emitting layer 330 facing the substrate 100. This can ensure that the light emitted from the side of the light-emitting layer 330 is not blocked by the second light-shielding portion 420. In this manner, the light can be emitted from the side of the light-emitting layer 330. Thus, the light utilization rate of the light-emitting element 300 is improved, thereby facilitating the improvement of the display brightness of the display panel 10. Moreover, when the light utilization rate of the light-emitting element 300 is improved, and when the display panel 10 needs a higher display brightness, a higher display brightness can be implemented only by providing a smaller drive signal for the light-emitting element 300, thereby facilitating the low power consumption of the display panel 10.

In other optional embodiments, FIG. 9 is a diagram illustrating the structure of a film layer of another display panel according to an embodiment of the present invention. Referring to FIG. 9, the surface of the side of a second light-shielding portion 420 facing away from a substrate 100 is a first surface 11. The surface of the side of a light-emitting element 300 facing away from the substrate 100 is a second surface 12. At least part of the first surfaces 11 are located on the side of the second surface 12 facing away from the substrate 100.

The at least part of the first surfaces 11 located on the side of the second surface 12 facing away from the substrate 100 can be understood that when the distance between the first surface 11 and the substrate 100 is a first distance, and the distance between the second surface 12 and the substrate 100 is a second distance, the first distance may be greater than the second distance. That is, the surface height of the first surface 11 may be greater than the surface height of the second surface with the plane in which the substrate 100 is located as a reference plane.

Specifically, the surface height of the first surface 11 of the second light-shielding portion 420 disposed between two adjacent light-emitting elements 300 is set to be greater than the surface height of the second surface 12 of a light-emitting element 300. Thus, the second light-shielding portion 420 can block at least part of light emitted from the light-emitting element 300 that propagates toward one side of an another light-emitting element 300 adjacent to the light-emitting element 300. Moreover, the mutual crosstalk between the light emitted from adjacent light-emitting elements 300 can be minimized, the contrast ratio of a display panel 10 can be improved, and the display effect can be improved. In this case, since the second light-shielding portion 420 is located between two adjacent light-emitting elements 300, the second light-shielding portion 420 does not block light emitted from a light-emitting element 300 toward the side facing away from the substrate 100. Thus, normal display light emission of the light-emitting element 300 is not affected.

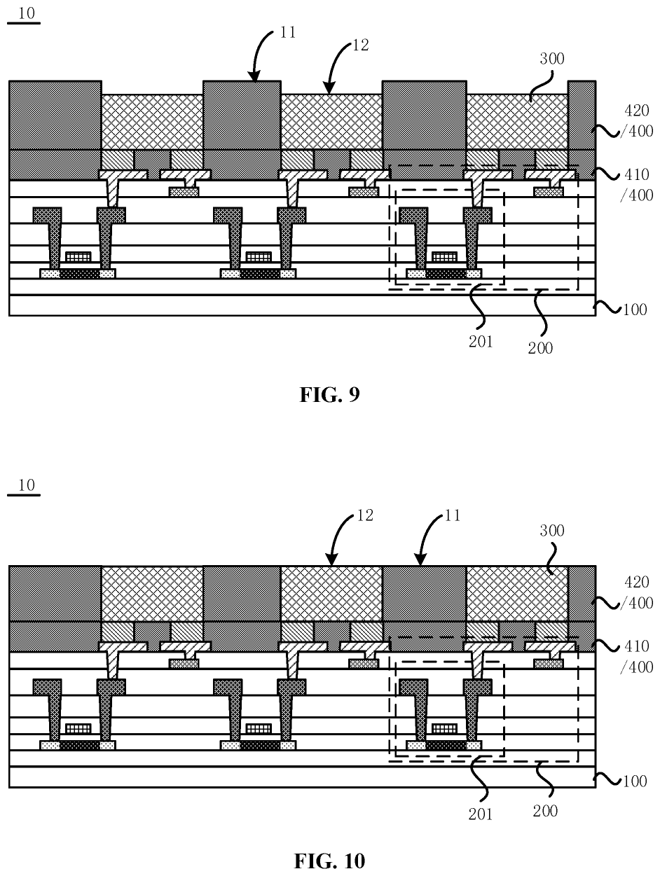

In an optional embodiment, referring to FIG. 10, at least part of a first surfaces 11 may also be flush with a second surface 12. In this case, it is to be understood that the surface height of at least part of the first surface 11 is equal to the surface height of the second surface 12 with the plane in which a substrate 100 is located as a reference plane. By setting the first surface 11 flush with the second surface 12, on the one hand, the mutual crosstalk between the light emitted from adjacent light-emitting elements 300 can be minimized. On the other hand, the step between the light-emitting element 300 and the light-shielding structure 400 can be reduced, thereby facilitating the subsequent preparation process.

It is to be understood that the preparation process of the light-shielding structure is after the preparation process of the light-emitting element. When the light-shielding structure is formed, the material of part of the light-shielding structure is located on the side of the light-emitting element facing away from the substrate, thereby affecting the normal display light emission of the light-emitting element. In this case, after the light-shielding structure is formed, the light-shielding structure on the side of the light-emitting element facing away from the substrate can be removed by patterning the light-shielding structure.

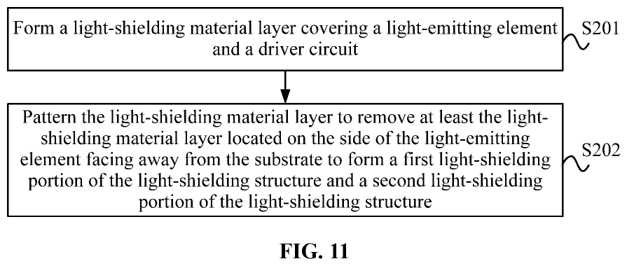

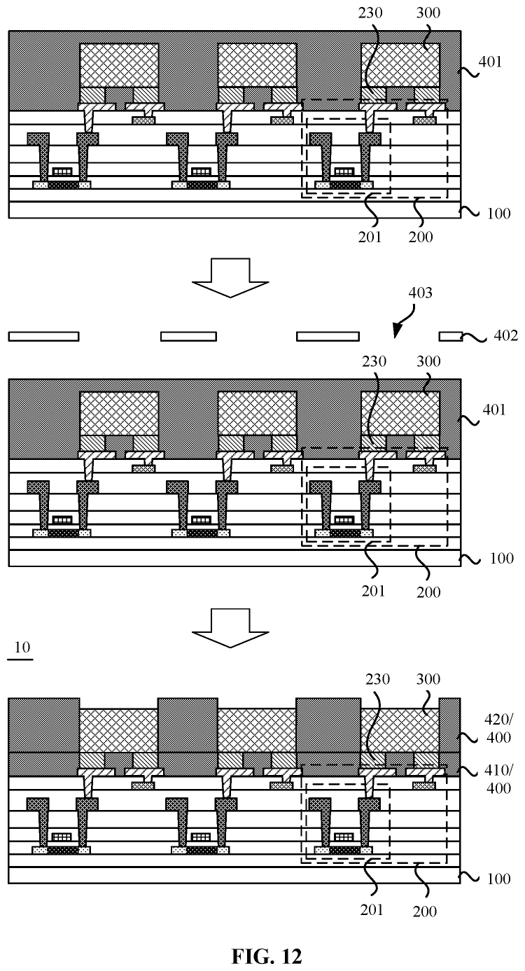

In an embodiment, FIG. 11 is a flowchart of a method for preparing a light-shielding structure according to an embodiment of the present invention. FIG. 12 is a diagram of a process for preparing a light-shielding structure according to an embodiment of the present invention. Referring to FIG. 11, the method for preparing a light-shielding structure includes the following steps.

In S201, a light-shielding material layer covering a light-emitting element and a driver circuit is formed.

In S202, the light-shielding material layer is patterned to remove at least the light-shielding material layer located on the side of the light-emitting element facing away from the substrate to form a first light-shielding portion of the light-shielding structure and a second light-shielding portion of the light-shielding structure.

Specifically, referring to FIG. 12, a manner of forming a light-shielding material layer 401 covering a light-emitting element 300 and a driver circuit 200 may include, but is not limited to, coating or printing. The light-shielding material layer 401 may include, but is not limited to, a photoresist. The light-shielding material layer 401 is prepared by a coating or printing technique on the side of the driver circuit 200 facing away from the substrate 100. Since the light-shielding material layer 401 has a certain fluidity at the time of preparation, the light-shielding material layer 401 can effectively fill the bottom of the light-emitting element 300 and the gap of a bonding electrode 230 and cover the light-emitting element 300 and the driver circuit 200. After the light-shielding material layer 401 is cured, the light-shielding material layer 401 located on the side of the light-emitting element 300 facing away from the substrate can be removed by etching the side of the light-emitting element 300 facing away from the substrate 100. Only the light-shielding material layer 401 located between the light-emitting element 300 and the thin-film transistor 201 and between two adjacent light-emitting elements 300 is retained to form a first light-shielding portion 410 of the light-shielding structure 400 and a second light-shielding portion 420 of the light-shielding structure 400. The first light-shielding portion 410 and the second light-shielding portion 420 may be both made of the light-shielding material layer 401. The same technique and the same process may be used to simplify the technique preparation process, reduce the process, and reduce the preparation cost.

It is to be understood that, when the light-shielding material layer includes a photoresist, the photoresist may be irradiated or radiated by the ultraviolet light, the electron beam, the ion beam, the X-ray, or the like, to change the solubility of the photoresist. Thus, the corresponding solution can be used to develop the photoresist, and the patterning of the light-shielding material layer can be implemented. The photoresist may include a positive photoresist or a negative photoresist.

In an embodiment, the light-shielding material layer includes a positive photoresist as an example. Patterning the light-shielding material layer includes patterning the light-shielding material layer by using a photolithography technique.

Specifically, with continued reference to FIG. 12, when the light-shielding material layer 401 is a positive photoresist, the part irradiated by light is degraded. Therefore, when the light-shielding material layer is patterned, a mask 402 may be disposed on the side of the light-shielding material layer 401 facing away from the substrate. The mask 402 includes openings 403. The openings 403 are located directly above the side of light-emitting elements 300 facing away from the substrate 100. When the light-shielding material 401 is exposed, the light-shielding material layer 401 directly above the side of the light-emitting elements 300 facing away from the substrate 100 is irradiated by light and degraded. When the light-shielding material layer 401 is developed, the degraded part of the light-shielding material layer 401 is dissolved by the developing solution. The part not degraded is left to form the first light-shielding portion 410 and the second light-shielding portion 420. In addition, the light-emitting elements 300 may act as a mask at the time of exposure to prevent degradation of the light-shielding material layer 401 at the bottom gap on the side of the light-emitting elements 300 facing the substrate 100 to form at least part of the first light-shielding portion 410. The mask 402 may mask directly above the gap between adjacent light-emitting elements 300 to prevent degradation of the light-shielding material layer 401 between the adjacent light-emitting elements 300 to form the second light-shielding portion 420.

It is to be noted that the preceding only exemplarily shows that the light-shielding material layer 401 is patterned by performing photolithography on the light-shielding material layer 401. After the light-shielding material layer 401 is patterned by using the photolithography technique, part of the light-shielding material layer 401 may still remain on the side of the light-emitting elements 300 facing away from the substrate. In this case, after the light-shielding structure is formed at least between thin-film transistors and the light-emitting elements, the light-shielding material layer remaining on the surface of the side of the light-emitting elements facing away from the substrate may be removed by using an ashing technique.

Specifically, the light-shielding material layer has a certain non-light-transmissive property. At the time of exposure, the light-shielding material layer directly above the side of the light-emitting elements facing away from the substrate may not be completely degraded. At the time of developing, there is part of the remaining light-shielding material layer. The remaining organic matter in the light-shielding material layer directly above the side of the light-emitting elements facing away from the substrate may be removed by high temperature. The remaining part may be dissolved by acid to remove the remaining light-shielding material layer directly above the side of the light-emitting elements facing away from the substrate.

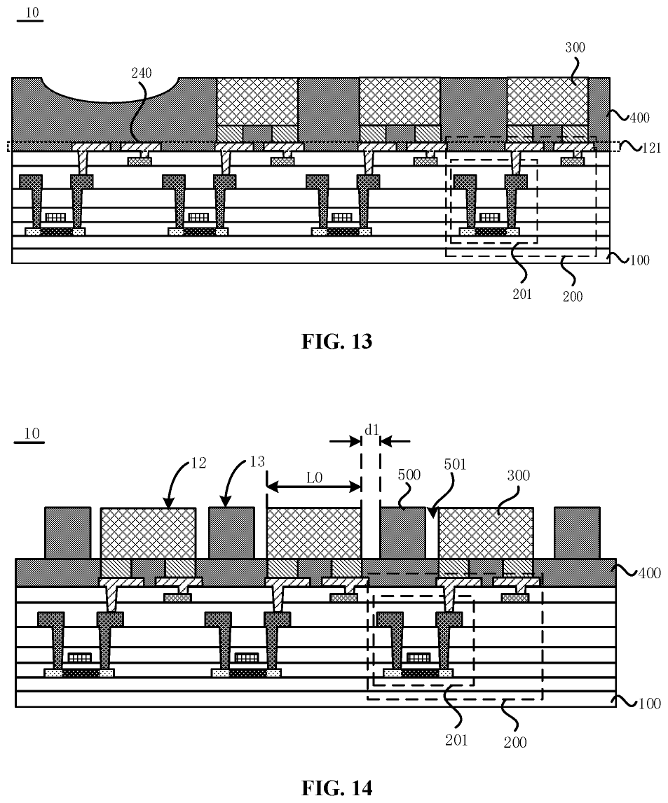

In an embodiment, FIG. 13 is a diagram illustrating the structure of a film layer of another display panel according to an embodiment of the present invention. Referring to FIG. 13, a display panel 10 also includes an electrode layer 121 located between driver circuits 200 and light-emitting elements 300. The electrode layer 121 includes bonding electrodes 230 and redundant electrodes 240. A light-emitting element 300 is electrically connected to a driver circuit 201 by a bonding electrode 230. The surface of the side of a light-shielding structure 400 facing away from a substrate 100 has a concave structure or a concave-convex structure. In the direction perpendicular to the plane in which the substrate 100 is located, the light-shielding structure 400 covers a redundant electrode 240. The concave structure or the concave-convex structure overlaps the redundant electrode 240.

The bonding electrodes 230 may be used for bonding light-emitting elements 300 transferred through mass transfer. After the light-emitting elements are transferred through mass transfer, the light-emitting elements 300 cannot normally display and emit light due to the influence of internal or external factors. In this case, the light-emitting elements 300 need to be repaired. Generally, redundant electrodes 240 are reserved in the display panel. Thus, light-emitting elements 300 can be disposed on the redundant electrodes 240 when the light-emitting elements 300 bonding on the bonding electrodes 230 cannot normally display and emit light, thereby ensuring that the display panel can normally display and emit light at this position. The redundant electrodes 240 and the bonding electrodes 230 have the same or similar structure. The redundant electrodes 240 and the bonding electrodes 230 are disposed in the same layer in the electrode layer 121.

It is to be understood that, in the preparation process of the display panel, light-emitting elements 300 are usually not disposed on the redundant electrodes 240 but only bonded on the bonding electrodes 230. After a light-emitting element 300 is disposed on one side of a driver circuit 200, a light-shielding material layer 401 is prepared on the side of the driver circuit 200 facing away from the substrate 100 by a technique such as coating. Due to the fluidity of the light-shielding material layer 401, the surface of the side of a redundant electrode 240 facing away from the substrate 100 forms an uneven structure such as a concave structure or a concave-convex structure. That is, the light-shielding material layer 401 at other positions flows to the redundant electrode 240. This can increase the thickness of the light-shielding material layer 401 at the position of the redundant electrode 240 to a certain extent. Although a concave structure or a concave-convex structure may be formed at the position of the redundant electrode 240 due to the influence of the technique, the light-shielding structure 400 covered the side of the redundant electrode 240 facing away from the substrate 100 can still have a high light-shielding capability. This can block light from propagating to the redundant electrode 240 and prevent unnecessary reflection.

In an embodiment, FIG. 14 is a diagram illustrating the structure of a film layer of another display panel according to an embodiment of the present invention. Referring to FIG. 14, a display panel 10 also includes a bank structure 500 located on the side of a light-shielding structure 400 facing away from a substrate 100 and located at least between two adjacent light-emitting elements 300. A first gap 501 is between the bank structure 500 and a light-emitting element 300. In the direction parallel to the plane in which the substrate 100 is located, the value range of the size d1 of the first gap 501 is 0 μm<d1<L0. L0 is the size of the light-emitting element 300 in the direction parallel to the plane in which the substrate 100 is located.

L0 is the size of a light-emitting element 300 in any direction parallel to the plane in which the substrate 100 is located. For example, when light-emitting elements 300 are arranged in an array, L0 may be the size of a light-emitting element 300 in the row direction or the size of a light-emitting element 300 in the column direction. This is not specifically limited in the embodiments of the present invention.

Specifically, the bank structure 500 has a certain light-blocking capability to block at least part of the light emitted from a light-emitting element 300 toward the side of the adjacent light-emitting element 300, reduce the mutual crosstalk between the light emitted from adjacent light-emitting elements 300, and improve the display contrast of the display panel 10. At the same time, the bank structure 500 may also have a certain reflection capability. Thus, at least part of light can be reflected by the bank structure 500 when reaching a position in which the bank structure 500 is located. In addition, since a first gap 501 exists between a light-emitting element 300 and a bank structure 500, the light emitted from the light-emitting element 300 facing the side of the bank structure 500 can change the optical path propagation direction after being reflected on the surface of the side of the bank structure 500 facing the light-emitting element 300. Thus, the reflected light can be emitted from the first gap 501 and propagated toward the side facing away from the substrate 100, thereby improving the light utilization rate of the light-emitting element 300 and facilitating the low power consumption of the display panel 10.

In an optional embodiment, the bank structure 500 and the light-shielding structure 400 may be made of the same material. Moreover, the bank structure 500 may be integrated with the light-shielding structure 400. At this time, corresponding light-shielding materials can be filled in a gap between a light-emitting element 300 and a thin-film transistor 201 and a gap between two adjacent light-emitting elements 300. Then, the filled light-shielding materials are patterned to form the light-shielding structure 400 and the bank structure 500, respectively. The first gap 501 is formed between the bank structure 500 and the light-emitting element 300. In this manner, the light-shielding structure 400 and the bank structure 500 are integrally formed, thereby facilitating the simplification of the technique preparation process and reducing the preparation cost of the display panel 10.

It is to be understood that when the material of the bank structure 500 is the same as the material of the light-shielding structure 400, the bank structure 500 and the light-shielding structure 400 may have the same optical density value and reflectance. In this case, both the bank structure 500 and the light-shielding structure 400 may include a photoresist material, for example, a black photoresist or a photoresist doped with titanium dioxide.

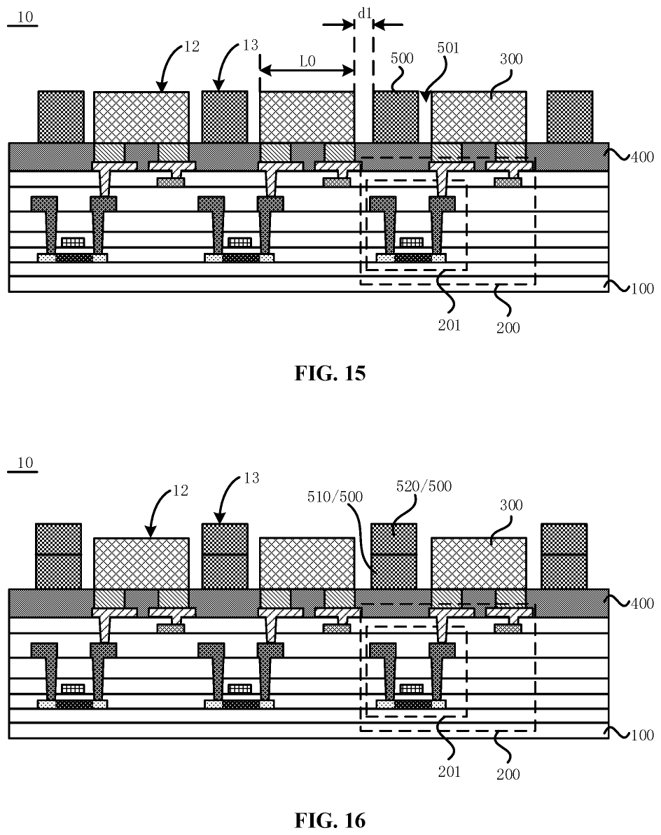

In other optional embodiment, as shown in FIG. 15, a bank structure 500 and a light-shielding structure 400 may also be made of different materials. In this case, the reflectance of the bank structure 500 may be greater than the reflectance of the light-shielding structure 400. Thus, the bank structure 500 has a large reflection capability. Moreover, the bank structure 500 can sufficiently reflect light emitted from the side of a light-emitting element 300 facing the bank structure 500, thereby causing the light emitted from the light-emitting element 300 to have a high utilization rate. At the same time, the light-shielding structure 400 has a small reflection capability. The reflectance of the external light in a display panel 10 can be reduced, thereby facilitating the improvement of the display contrast of the display panel 10.

In an optional embodiment, when the bank structure 500 and the light-shielding structure 400 are made of different materials, the light-shielding structure 400 and the bank structure 500 may be formed in steps. That is, after the light-shielding structure 400 is disposed at least between light-emitting elements 300 and thin-film transistors 201, the bank structure 500 is disposed between two adjacent light-emitting elements 300.

It is to be understood that since the material of the bank structure 500 is different from the material of the light-shielding structure 400, the bank structure 500 may include a material having a larger reflectance, and the light-shielding structure 400 may include a material having a larger light-shielding capability. For example, the bank structure 500 may include a photoresist doped with titanium dioxide. The light-shielding structure 400 may include a black photoresist.

In an embodiment, referring to FIG. 14 or FIG. 15, the surface of the side of a bank structure 500 facing away from the substrate 100 is a third surface 13. The surface of the side of a light-emitting element 300 facing away from the substrate is a second surface 12. At least part of the third surface 13 is flush with the second surface 12.

The third surface 13 of the bank structure 500 flush with the second surface 12 of the light-emitting element 300 can be understood that when the distance between the third surface 13 of the bank structure 500 and the substrate 100 is a first distance, and the distance between the second surface 12 of the light-emitting element 300 and the substrate 100 is a second distance, the first distance is equivalent to the second distance. That is, the third surface 13 of the bank structure 500 and the second surface 12 of the light-emitting element 300 have the same surface height with the plane in which the substrate 100 is located as a reference plane.

Specifically, the third surface 13 of the bank structure 500 is flush with the second surface 12 of the light-emitting element 300. Thus, the display panel 10 has an even upper surface after the light-emitting element 300 and the bank structure 500 are prepared. Moreover, the subsequent film layer can be prepared based on the even surface. Alternatively, the subsequent assembly structure can be assembled based on the even surface, thereby facilitating the simplification of the subsequent film layer preparation process or the assembly of the assembly structure. At the same time, a bank structure 500 can block the light emitted from a light-emitting element 300 to propagate toward the side of a light-emitting element 300 adjacent to the light-emitting element 300. When the third surface 13 of the bank structure 500 is flush with the second surface of the light-emitting element 300, the light emitted from the light-emitting element 300 can be prevented from propagating through the bank structure 500 to the position in which a light-emitting element 300 adjacent to the light-emitting element 300 is located. Thus, the mutual crosstalk between the light emitted from adjacent light-emitting elements 300 can be minimized, and the display contrast of the display panel 10 can be improved. Further, the display effect of the display panel 10 can be improved.

In other optional embodiment, as shown in FIG. 16, at least part of the third surfaces 13 of a bank structure 500 may also be located on the side of the second surface 12 of a light-emitting element 300 facing away from a substrate. In this case, it is to be understood that when the distance between the third surface 13 of the bank structure 500 and the substrate 100 is a first distance, and the distance between the second surface 12 of the light-emitting element 300 and the substrate 100 is a second distance, the first distance is greater than the second distance. That is, the surface height of the third surface 13 of the bank structure 500 is greater than the surface height of the second surface 12 of the light-emitting element 300 with the plane in which the substrate 100 is located as a reference plane. In this manner, the light emitted from the light-emitting element 300 can also be prevented from propagating through the bank structure 500 to the position in which a light-emitting element 300 adjacent to the light-emitting element 300 is located. Thus, the mutual crosstalk between the light emitted from adjacent light-emitting elements 300 can be minimized, and the display contrast of a display panel 10 can be improved. Further, the display effect of the display panel 10 can be improved.

It is to be noted that at least part of the third surfaces 13 is flush with the second surface 12. Moreover/alternatively, at least part of the third surfaces 13 is located on the side of the second surface 12 facing away from the substrate 100. It may be that the surface height of all of the third surface 13 is greater than or equal to the surface height of the second surface 12 with the plane in which the substrate 100 is located as a reference plane. Alternatively, the surface height of part of the third surface 13 is greater than or equal to the surface height of the second surface 12. This is not specifically limited in the embodiments of the present invention. Those skilled in the art may set according to actual situations.

In an embodiment, a bank structure includes a first bank portion and a second bank portion. The second bank portion is located on the side of the first bank portion facing away from the substrate. The size of the second bank portion is less than or equal to the size of the first bank portion in the direction parallel to the plane in which the substrate is located.

In an example embodiment, as shown in FIG. 16, the section of the bank structure 500 may be in the shape of a rectangle. In this case, in the direction parallel to the plane in which the substrate is located, the size of the first bank portion 510 is equal to the size of the second bank portion 520. That is, the upper and lower widths of the bank structure 500 are the same. In this manner, the light-blocking capability of the bank structure 500 at each position is kept uniform. Thus, the optical crosstalk generated between the light emitted from two adjacent light-emitting elements 300 can be prevented.

In another example embodiment, as shown in FIG. 17, the section of a bank structure is in the shape of an isosceles trapezoid. In this case, in the direction parallel to the plane in which the substrate is located, the size of a first bank portion 510 is greater to the size of a second bank portion 520. That is, the bank structure 500 is a structure having a narrow upper portion and a wide lower portion. In this manner, by setting the size of the second bank portion 520 to be less than or equal to the size of the first bank portion 510, sufficient space can be reserved for the light emitted from the side surface of a light-emitting element 300. Thus, the light propagating to the bank structure 500 can be reflected by the bank structure 500 and then emitted along the side facing away from the substrate 100 again, thereby improving the light utilization rate of the light-emitting element 300.

It is to be understood that the section of the bank structure 500 may also be in the shape of a structure having a straight edge such as a triangle or a structure having an arc edge. The main function of the bank structure 500 is to prevent the light emitted from two adjacent light-emitting elements 300 from generating crosstalk and to reflect the light emitted from the side surface of a light-emitting element 300 to improve the light utilization rate. On the premise that this condition is satisfied, the shape of the section of the bank structure 500 is not specifically limited in the embodiments of the present invention. For ease of description, without otherwise specified, the technical solutions in the embodiments of the present invention are described in the following by taking the shape of the section of the bank structure 500 as an isosceles trapezoid as an example.

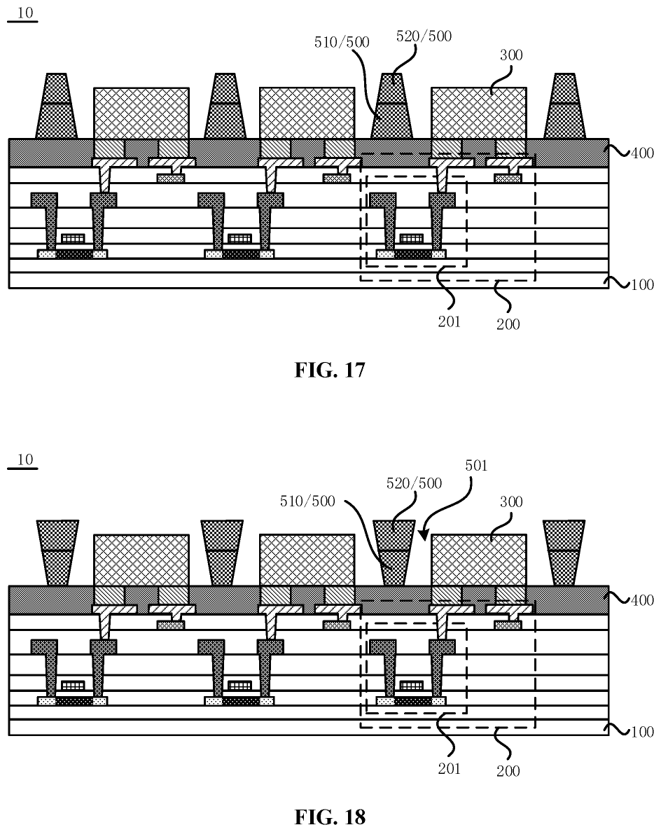

In an embodiment, referring to FIG. 18, when a first gap 501 is disposed between a bank structure 500 and a light-emitting element 300, the size of the first gap 501 between a first bank portion 510 and the light-emitting element 300 may be greater than or equal to the size of the first gap 501 between a second bank portion 520 and the light-emitting element 300. In this manner, part of the external ambient light entering the first gap 501 is still limited in the first gap after being reflected on the bank structure 500 and/or the light-shielding structure 400 and cannot be emitted. Thus, the reflection on the external ambient light can be reduced so that the display panel has a high display contrast.

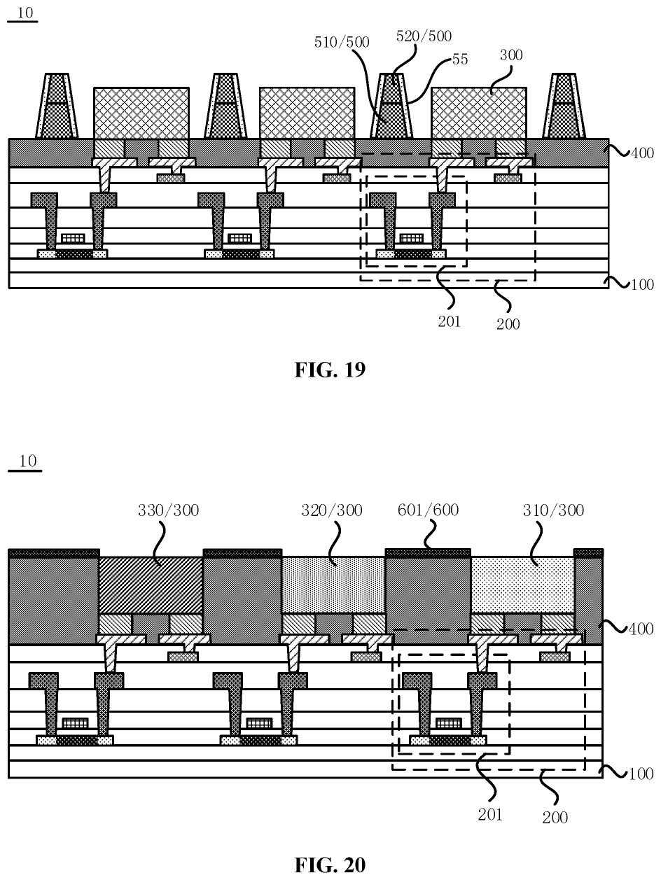

In an embodiment, FIG. 19 is a diagram illustrating the structure of a film layer of another display panel according to an embodiment of the present invention. As shown in FIG. 19, a display panel 10 also includes reflection structures 55. A reflection structure 55 is located on the surface of the side of a bank structure 500 facing a light-emitting element 300. The reflectance of the reflection structure 55 is greater than the reflectance of the bank structure 500. The reflectance of the reflection structure 55 is greater than the reflectance of a light-shielding structure 400. In this manner, the reflection structure 55 having a large reflectivity is disposed on the side of the bank structure 500 facing the light-emitting element 300. Thus, the reflection structure 55 can sufficiently reflect the light emitted from the side surface of the light-emitting element 300, thereby improving the light utilization rate, and then facilitating the improvement of the display brightness of the display panel.

It is to be understood that the light-shielding structure 400 and the bank structure 500 have a certain reflection capability for light. To prevent a case in which the display contrast of the display panel 10 is affected by reflection of the external ambient light by the light-shielding structure 400 and/or the bank structure 500, an anti-reflective structure such as a polarizer may be disposed on the side of the light-emitting element 300 facing away from the substrate 100.

In an optional embodiment, FIG. 20 is a diagram illustrating the structure of a film layer of another display panel according to an embodiment of the present invention. Referring to FIG. 20, a display panel 10 also includes a color resist layer 600. The color resist layer 600 is located on at least the side of driver circuits 200 facing away from a substrate 100. The color resist layer 600 includes multiple color resist structures 601. Multiple light-emitting elements 300 include light-emitting elements (310, 320, and 330) of multiple colors. In the direction perpendicular to the plane in which the substrate 100 is located, a color resist structure 601 overlaps at least the gap between two adjacent light-emitting elements 300.

The multiple light-emitting elements 30 may include multiple light-emitting elements of different colors, including, for example, a red light-emitting element 310, a green light-emitting element 320, and a blue light-emitting element 330. The red light-emitting element 310, the green light-emitting element 320, and the blue light-emitting element 330 emit red light, green light, and blue light, respectively, to implement the display of a color image.

Specifically, when the external ambient light enters the display panel 10 through the gap between two adjacent light-emitting elements 300, the external ambient light is reflected on the structure having the reflection capability. Thus, an obvious light-dark contrast cannot be formed between the two adjacent light-emitting elements 300, thereby affecting the display contrast of the display panel 10. A color resist structure 601 overlaps the gap between two adjacent light-emitting elements 300. The color resist structure 601 blocks at least part of the light passing through. Thus, the external ambient light entering the display panel 10 can be reduced, further reducing the reflection of the external ambient light by the structure having the reflection capability in the display panel 10. Moreover, the light emitted from the two adjacent light-emitting elements 300 has a high light-dark contrast, thereby improving the display effect of the display panel. At the same time, when the color resist structure 601 overlaps the gap between the two adjacent light-emitting elements 300, the color resist structure 601 can block the light emitted from the two adjacent light-emitting elements 300 to reduce the mutual crosstalk between the light emitted from the adjacent light-emitting elements 300 and increase the contrast ratio of the display panel 10. In addition, the color resist structure 601 can reduce the external ambient light entering through the gap between two adjacent light-emitting elements 300. Further, the light reaching a thin-film transistor 201 can be reduced. Thus, the leakage current of the thin-film transistor 201 can be reduced. Further, the accuracy of the drive signal provided by the thin-film transistor 201 can be improved so that the light-emitting element 300 can emit light accurately. The color resist structure 601 may include a black color resist to be able to block light of different colors. Alternatively, the color resist structure 601 may also include color resists of different colors. In this case, the color resist structure 601 can transmit light of the corresponding color while blocking light of other colors.

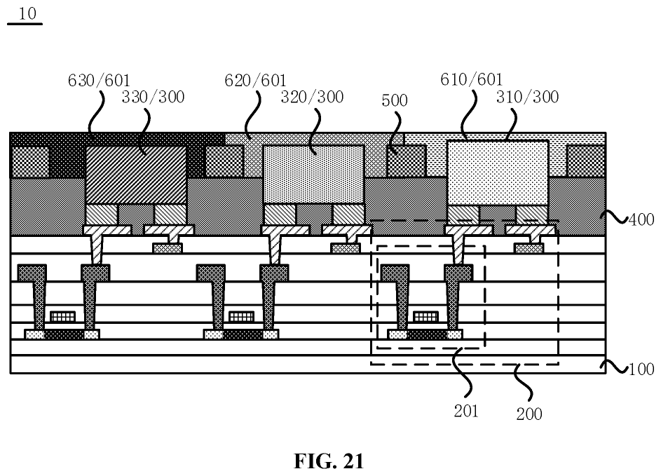

In an embodiment, FIG. 21 is a diagram illustrating the structure of a film layer of another display panel according to an embodiment of the present invention. Referring to FIG. 20, when the light-emitting elements 300 include a red light-emitting element 310, a blue light-emitting element 330, and a green light-emitting element 320, a color resist structure 601 includes a first color resist structure 610, a second color resist structure 630, and a third color resist structure 620. In the direction perpendicular to the plane in which the substrate 100 is located, the first color resist structure 610 overlaps the red light-emitting element 310. The second color resist structure 630 overlaps the blue light-emitting element 330. The third color resist structure 620 overlaps the green light-emitting element 320. The first color resist structure 610 includes a red color resist or a yellow color resist. The second color resist structure 630 includes a blue color resist. The third color resist structure 630 includes a green color resist or a yellow color resist.

The red color resist can transmit red light while blocking light of other colors. The green color resist can transmit green light while blocking light of other colors. The yellow color resist can transmit yellow and orange light while blocking light of other colors. The blue color resist can transmit blue light while blocking light of other colors.

Specifically, when the first color resist structure 610 includes a red color resist or a yellow color resist, the first color resist structure 610 can transmit red light emitted from the red light-emitting element 310 while blocking light of other colors. Thus, display light close to the light emitted from the red light-emitting element 310 is displayed at the position in which the red light-emitting element 310 is located, thereby improving the accuracy of display light emission at the position in which the red light-emitting element 310 is located. Similarly, when the second color resist structure 630 includes a blue color resist, the second color resist structure 630 can transmit blue light emitted from the blue light-emitting element 330 while blocking light of other colors. Thus, blue light is displayed at a position in which the blue light-emitting element 330 is located, thereby improving the accuracy of light emission at the position in which the blue light-emitting element 330 is located. Accordingly, when the third color resist structure 620 includes a green color resist or a yellow color resist, the third color resist structure 620 can transmit green light emitted from the green light-emitting element 320 while blocking light of other colors. Thus, the accuracy of light emission at the position in which the green light-emitting element 320 is located can be improved. Thus, the first color resist structure 610, the second color resist structure 630, and the third color resist structure 620 are disposed. Unnecessary reflected light in the display panel 10 can be further reduced, and the display contrast of the display panel 10 can be improved.

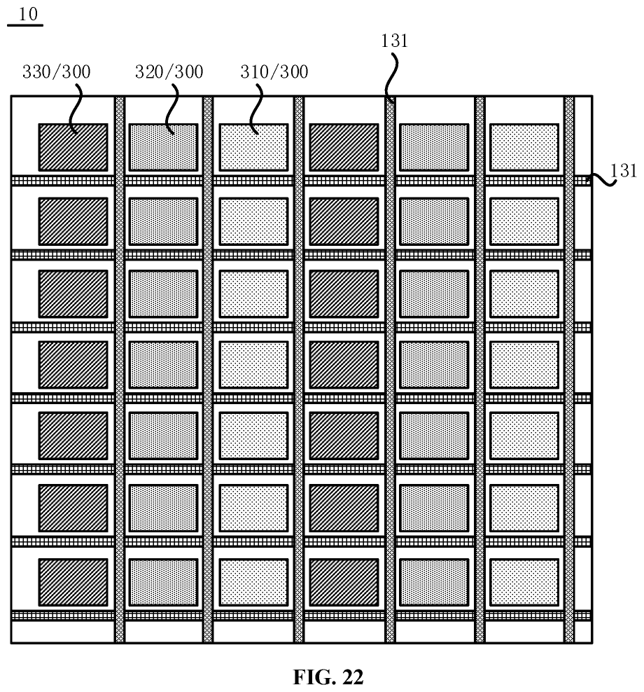

In an embodiment, FIG. 22 is a top diagram illustrating the structure of a display panel according to an embodiment of the present invention. FIG. 23 is a diagram illustrating the structure of a film layer of another display panel according to an embodiment of the present invention. Referring to FIG. 22 and FIG. 23, a display panel 10 also includes multiple first signal lines 131. The multiple first signal lines 131 are located between a substrate 100 and light-emitting elements 300. The first signal lines 131 are electrically connected to the light-emitting elements 300 and/or driver circuits 200. In the direction perpendicular to the plane in which the substrate 100 is located, at least part of the first signal lines 131 do not overlap the light-emitting elements 300. A second color resist structure 630 covers the at least part of the first signal lines 131 that do not overlap the light-emitting elements 300.

A first signal line 131 may be a signal line electrically connected to the source or drain of a thin-film transistor 201 to provide a corresponding electrical signal for the source or drain of the thin-film transistor 201. Thus, the thin-film transistor 201 can transmit the electrical signal to other devices electrically connected to the thin-film transistor 201. Alternatively, a first signal line 131 may be a signal line electrically connected to the gate of a thin-film transistor 201 to provide a corresponding electrical signal for the gate of the thin-film transistor 201 to control the turn-on or turn-off of the thin-film transistor 201. The specific connection mode of a first signal line 131 and the type of the electrical signal transmitted by the first signal line 131 are not specifically limited in the embodiments of the present invention.

Specifically, since the first signal line 131 is used for transmitting an electrical signal, the first signal line 131 should have a certain conductive capability. In this case, the material of the first signal line 131 may include a material having a conductive function, such as a metal, so that the first signal line has a certain reflection capability. Generally, the light reflected by the first signal line includes yellow and orange light. The second color resist structure 630 can cover the side of the first signal line facing away from the substrate so that the second color resist structure 630 can prevent light excluding blue light from reaching the first signal line 131. Moreover, the yellow and orange light reflected by the first signal line 131 cannot be transmitted through the second color resist structure 630, thereby reducing unnecessary reflection due to the first signal line 131. In addition, since the second color resist structure 630 covering at least part of the first signal lines 131 can be prepared in the same process as the second color resist structure 630 overlapping the blue light-emitting element 330, the technique preparation process can be reduced, and the preparation cost can be reduced.

It is to be understood that the preceding only takes the light-shielding structure located between driver circuits and light-emitting elements as an example. In the embodiments of the present invention, the metal and other structures in a driver circuit also have a certain light-shielding capability. In this case, at least part of structure in a driver circuit can be reused as at least part of the light-shielding structure to simplify the technique preparation process.

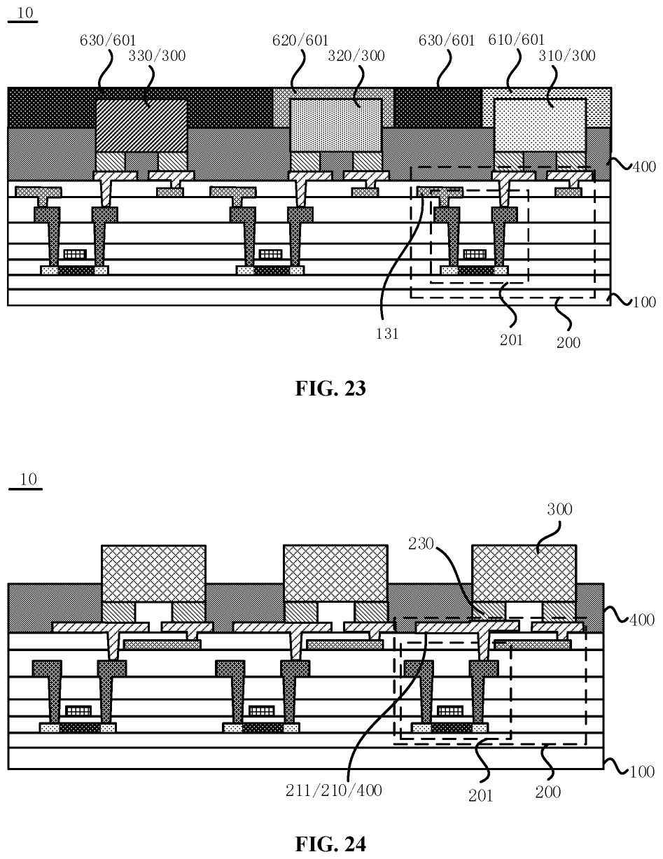

In an embodiment, FIG. 24 is a diagram illustrating the structure of a film layer of another display panel according to an embodiment of the present invention. Referring to FIG. 24, a driver circuit 200 includes a first metal structure 211 located on the side of the active layer of a thin-film transistor 201 facing away from a substrate 100. At least part of a light-shielding structure 400 and the first metal structure 211 are disposed in the same layer.

The first metal structure 211 may be any structure located between the active layer of the thin-film transistor 201 and a light-emitting element 300. Exemplarily, the first metal structure 211 may be a lap join structure 210. In this case, at least part of the light-shielding structure 400 and the first metal structure 211 are disposed in the same layer. The at least part of the light-shielding structure 400 may be integrated with the first metal structure 211. That is, part of the first metal structure 211 is reused as at least part of the light-shielding structure 400. Thus, the light-shielding action can be implemented without additional arrangement of the part of the light-shielding structure 400. This facilitates the simplification of the technique preparation process of the display panel 10 and reduces the film layer structure of the display panel 10, further facilitating the low cost and light and thinning of the display panel 10.

It is to be understood that the material of the first metal structure 211 is a metal material and may include, for example, a metal material such as Ti/Al/Ti or Mo/Al/Mo. In this case, when the first metal structure 211 is reused as at least part of the light-shielding structure 400, light emitted from the side of the light-emitting element 300 facing the substrate 100 can be reflected, thereby effectively improving the light utilization rate.

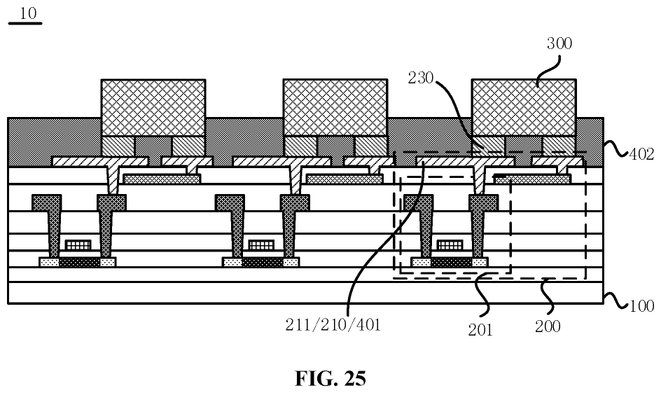

In an embodiment, FIG. 25 is a diagram illustrating the structure of a film layer of another display panel according to an embodiment of the present invention. Referring to FIG. 25, a light-shielding structure 400 disposed in the same layer with a first metal structure 211 is a first light-shielding structure 401. The light-shielding structure 400 also includes a second light-shielding structure 402. The second light-shielding structure 402 is located on the side of the first light-shielding structure 401 facing away from a substrate 100. In the direction perpendicular to the plane in which the substrate 100 is located, the second light-shielding structure 402 covers the first light-shielding structure 401. The reflectance of the second light-shielding structure 402 is less than the reflectance of the first light-shielding structure 401.

Specifically, the first metal structure 211 has a certain reflection capability. When the first light-shielding structure 401 and the first metal structure 211 are disposed in the same layer, the first light-shielding structure 401 also has a certain reflection capability. The second light-shielding structure 402 is disposed on the side of the first light-shielding structure 401 facing away from the active layer of a thin-film transistor 201. Thus, the second light-shielding structure 402 can prevent the light reflected by the first light-shielding structure 401 from being emitted toward the side facing away from the substrate 100, thereby effectively reducing the reflected light in the display panel 10. At the same time, in the direction perpendicular to the plane in which the substrate 100 is located, both the first light-shielding structure 401 and the second light-shielding structure 402 overlap the active layer of the thin-film transistor 201. Thus, the first light-shielding structure 401 and the second light-shielding structure 402 can simultaneously block at least part of light propagating to the active layer of the thin-film transistor 201. That is, the light passing through the second light-shielding structure 402 can be shielded by the first light-shielding structure 401, thereby further reducing the light propagating to the active layer of the thin-film transistor 201. Moreover, the active layer of the thin-film transistor 201 is prevented from being affected by the light, and thus unable to provide an accurate drive signal to a light-emitting element. In addition, the second light-shielding structure 402 has a small reflectance. The emission of ambient light entering from the outside and reaching the light-shielding structure 400 can be reduced by covering the first light-shielding structure 401 with the second light-shielding structure 402. After passing through the second light-shielding structure 402 to reach the first light-shielding structure 401 and being reflected by the first light-shielding structure 401, a small portion of the light can be blocked by the first light-shielding structure 401. Thus, the reflected light in the display panel can be reduced, and the influence of the reflected light on the display light emission of the display panel 10 can be avoided, thereby facilitating the improvement of the display contrast and display effect of the display panel 10.

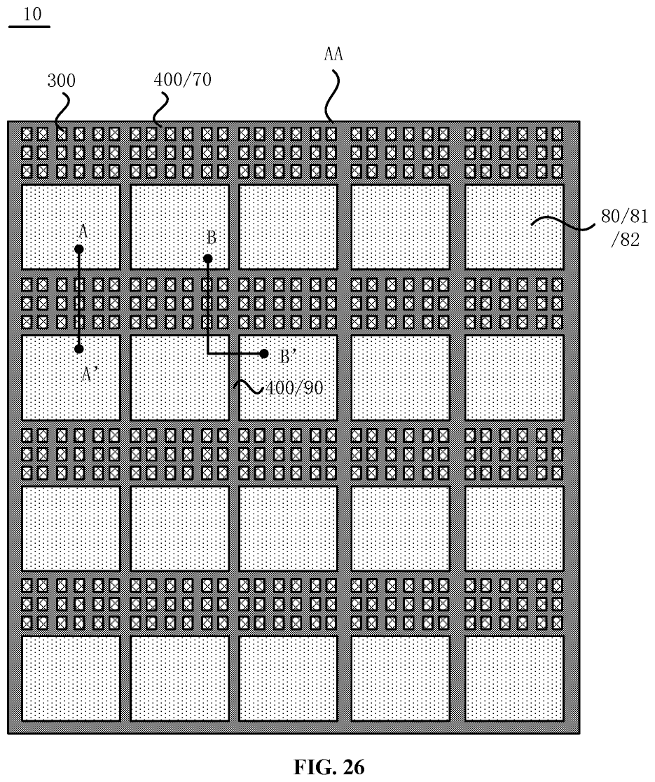

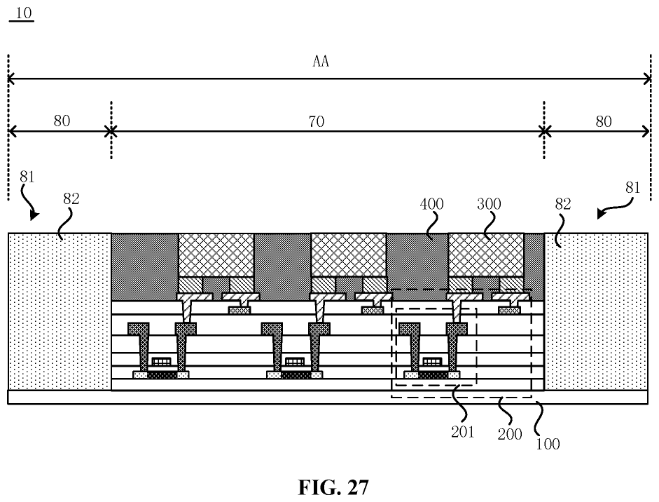

In an embodiment, FIG. 26 is a top diagram illustrating the structure of another display panel according to an embodiment of the present invention. FIG. 27 is a section structure diagram taken along section A-A′ in FIG. 26. Referring to FIG. 26 and FIG. 27, a display panel 10 includes a display region AA. The display region AA includes at least one light-transmissive hole region 80 and a pixel region 70 located on at least one side of the at least one light-transmissive hole region 80. Light-emitting elements 300 and driver circuits 200 are both located in the pixel region 70. A light-transmissive hole region 80 is provided with light-transmissive holes 81. The light-transmissive holes 81 penetrate through at least part of film layers of the driver circuits 200. At least part of the light-transmissive holes 81 are provided with a transparent structure 82.

A light-transmissive hole region 80 can be used for providing a photosensitive element such as a camera, an infrared sensor, or a fingerprint recognition element. Alternatively, a light-transmissive hole region 80 may be a transparent display region with a high transmittance. In this case, the display panel 10 may be a transparent display panel. Thus, the display panel may be applied to a display device such as an in-vehicle heads-up display or a window display.

Specifically, by disposing driver circuits 200 and light-emitting elements 300 in the pixel region 70, the driver circuits 200 can drive the light-emitting elements 300 to emit light. When the light-emitting elements 300 emit light, the light emitted from the light-emitting elements 300 can be radiated to light-transmissive hole regions 80. Thus, the light-transmissive hole regions 80 can also display an image of a corresponding content. At the same time, a driver circuit 200 includes a semiconductor layer, a conductive layer, an insulation layer, and the like. Thus, part of the film structure in the driver circuit 200 has a certain blocking action for light. At least part of the film layer of the driver circuit having the light-blocking action in the light-transmissive hole region 80 can be removed after each structure of the driver circuit 200 is formed. Only the film layer having a high light transmittance is retained to form a light-transmissive hole 81 penetrating through at least part of the film layer of the driver circuit 200.

In an optional embodiment, film layers of all driver circuits 200 in the light-transmissive hole region 80 can be removed to form light-transmissive holes 81 penetrating through the film layers of the driver circuits 200. Thus, the light-transmissive hole region 80 can have a high light transmittance.

In addition, a light-transmissive hole 81 may be provided with a transparent structure 82. The transparent structure 82 includes, but is not limited to, a transparent optically clear adhesive or a pixel-level transparent encapsulating adhesive. Thus, the light-transmissive hole provided with the transparent structure 82 can still have a high light transmittance. At the same time, by disposing transparent structures 82 in at least part of light-transmissive holes 81, the support property of the light-transmissive hole region 80 can be increased. Thus, the display panel 10 in the light-transmissive hole region 80 is not easily damaged by external impact.

In an embodiment, with continued reference to FIG. 26 and FIG. 27, the surface of the side of a transparent structure 82 facing the pixel region 70 is in contact with a light-shielding structure

400. Thus, no gap is left between the transparent structure 82 and the light-shielding structure 400. Moreover, the light-shielding structure 400 and the transparent structure 82 can cooperate with each other to form a protective structure for a driver circuit 200, thereby preventing the driver circuit 200 from being exposed and corroded by water and oxygen in the atmosphere. Thus, the service life of the driver circuit 200 can be prolonged, that is, the service life of the display panel can be prolonged.

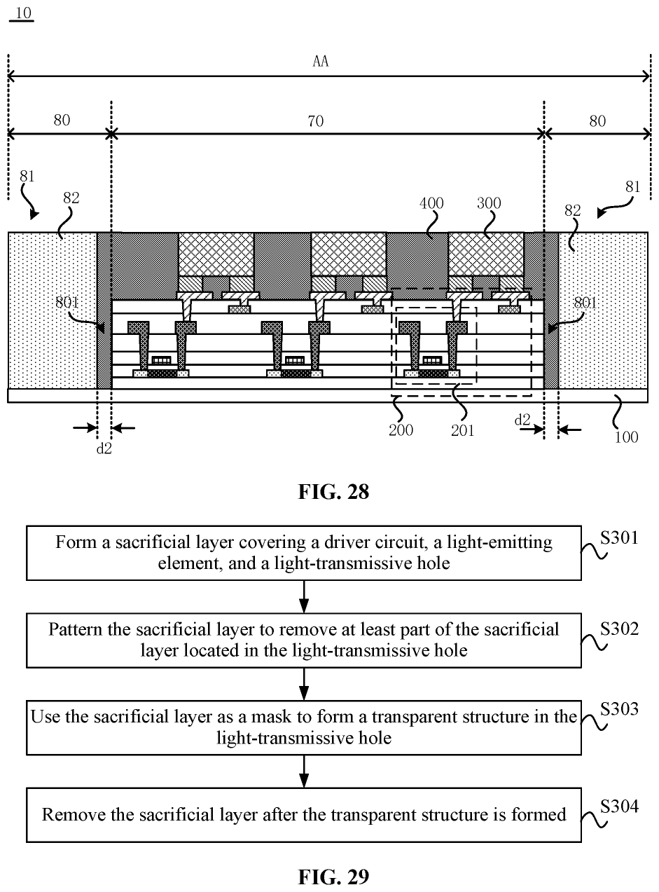

In an embodiment, FIG. 28 is another section structure diagram taken along section A-A′ in FIG. 26. Referring to FIG. 28, a second gap 801 is disposed between a transparent structure 82 and a pixel region 70. A light-shielding structure 400 is located in the second gap 801.

The transparent structure 82 is filled in at least part of a light-transmissive hole 81. That is, the transparent structure 82 may be filled in the entire light-transmissive hole 80. Alternatively, the transparent structure 82 may be filled in part of the light-transmissive hole 81. When the transparent structure 82 is filled only in part of a light-transmissive hole 81, a second gap 801 may be disposed between the transparent structure 82 and the pixel region 70. By filling the second gap 801 with the material of the light-shielding structure 400, the light-shielding structure 400 can cover the side wall of the light-transmissive hole 81, that is, the surface of the side of a driver circuit 200 facing a light-transmissive hole region 80. Thus, this part of the light-shielding structure 400 can shield the light entering from the light-transmissive hole 81, thereby avoiding the light from affecting the activity of carriers in the active layer of a thin-film transistor 201. Moreover, the accuracy of a drive signal provided by the thin-film transistor 201 is improved, and the accuracy of the light emission of a light-emitting element 300 is improved.

In an optional embodiment, the value range of the size d2 of the second gap 801 may be 0.5 μm≤d2≤15 μm. In this manner, it is possible to ensure that the light-shielding structure 400 has a sufficiently large light-shielding capability at the second gap 801, and that the light-shielding structure 400 does not occupy a large size of the light-transmissive hole region 80. Thus, the light-transmissive hole region 80 has a sufficiently large light-transmissive size, thereby ensuring that the light-transmissive hole region 80 has a sufficient light flux to satisfy the photosensitive requirement of a photosensitive element or satisfy the display requirement of the transparent display.

It is to be understood that the process of disposing the transparent structure in the light-transmissive hole region may be before or after disposing the light-shielding structure. This is not specifically limited in the embodiments of the present invention. When the transparent structure in the light-transmissive hole region is located before the light-shielding structure is disposed, the transparent structure may serve as a template for the light-shielding structure.

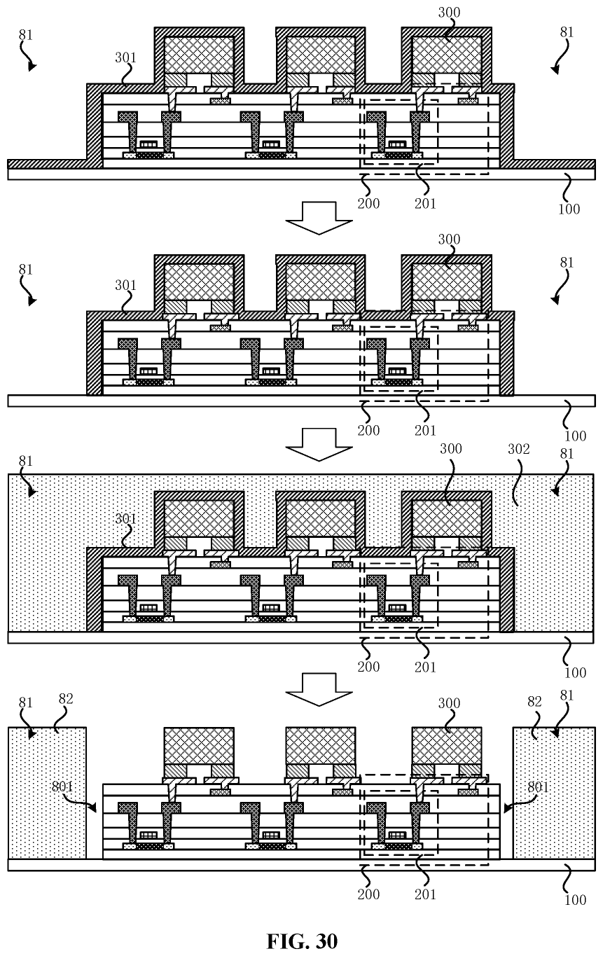

In an embodiment, for example, a transparent structure is formed before a light-shielding structure is formed at least between a thin-film transistor and a light-emitting element. FIG. 29 is a flowchart of a method for preparing a transparent structure according to an embodiment of the present invention. FIG. 30 is a diagram of a process for preparing a transparent structure according to an embodiment of the present invention. Referring to FIG. 29, the method for preparing a transparent structure includes the following steps.

In S301, a sacrificial layer covering a driver circuit, a light-emitting element, and a light-transmissive hole is formed.

The sacrificial layer may include silicon oxide, polysilicon, photoresist and other materials that can be etched off by a chemical etchant.

In S302, the sacrificial layer is patterned to remove at least part of the sacrificial layer located in the light-transmissive hole.

The manner of patterning the sacrificial layer may include, but is not limited to, etching or photolithography. After the sacrificial layer is patterned, only at least part of the sacrificial layer in the light-transmissive hole may be removed, while the sacrificial layer at other locations is retained. Thus, the sacrificial layer can be used as a mask plate with an opening.

In S303, the sacrificial layer is used as a mask to form a transparent structure in the light-transmissive hole.

Specifically, referring to FIG. 30, after at least part of a sacrificial layer 301 in a light-transmissive hole 81 is removed, the sacrificial layer 301 is formed into a mask plate having an opening. At this time, with the sacrificial layer 301 being a mask, a transparent material layer 302 can be filled in the light-transmissive hole 81 through the opening of the sacrificial layer 301. Thus, a transparent structure 82 is formed in the light-transmissive hole 81.

In S304, after the transparent structure is formed, the sacrificial layer is removed.

Specifically, with continued reference to FIG. 30, after the transparent structure 82 is formed, the transparent material layer 302 is cured and retained in the light-transmissive hole 81. At this time, all of the sacrificial layer may be removed by using a corresponding chemical etchant. When the sacrificial layer 301 is removed, the transparent material layer 302 on the side of the sacrificial layer 301 facing away from a substrate 100 may also be removed together. Only the transparent material layer 302 in the light-transmissive hole 81 in which the transparent structure 82 needs to be disposed is retained.

Thus, by using the sacrificial layer as a mask, the transparent structure with the opposite pattern to the sacrificial layer is formed. The transparent structure does not need to be patterned. Thus, the aging and damage of the transparent structure in the patterning process can be avoided, thereby avoiding affecting the light-transmissive property of the transparent structure.

It is to be understood that the formation manner of the transparent structure is only the exemplary formation manner of the transparent structure in the embodiments of the present invention. In other embodiments of the present invention, the transparent structure may be formed by patterning the material of the transparent structure.

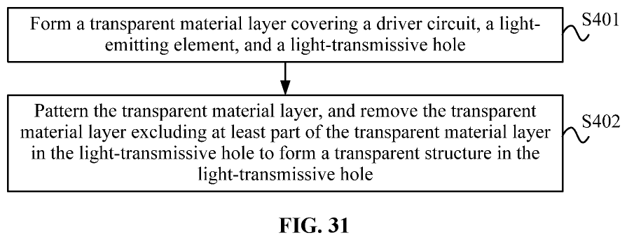

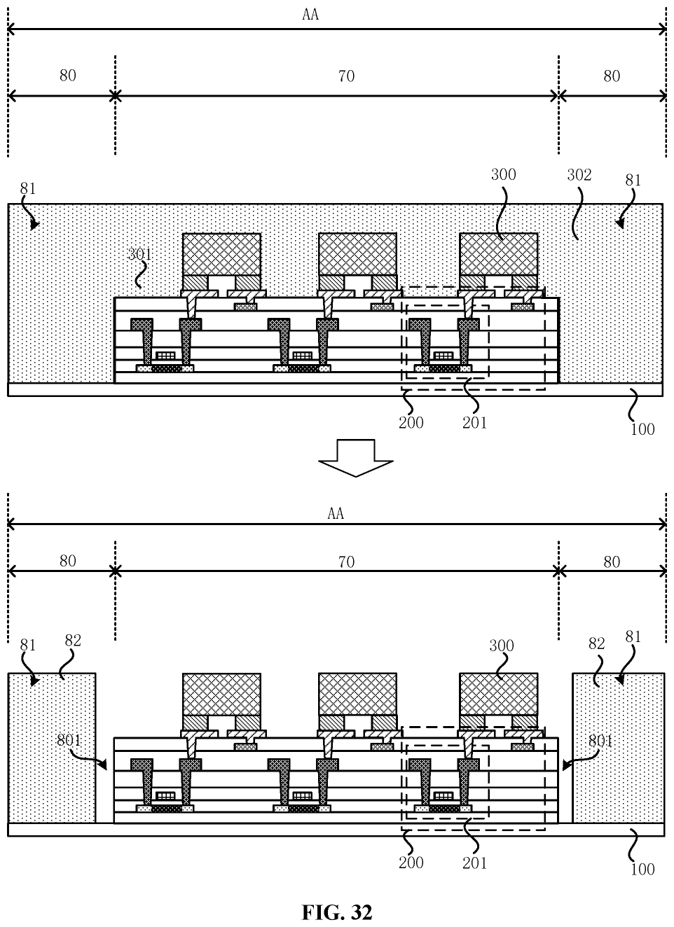

In an embodiment, FIG. 31 is a flowchart of another method for preparing a transparent structure according to an embodiment of the present invention. FIG. 32 is a diagram of another process for preparing a transparent structure according to an embodiment of the present invention. Referring to FIG. 31, the method for preparing a light-shielding structure includes the following steps.

In S401, a transparent material layer covering a driver circuit, a light-emitting element, and a light-transmissive hole is formed.

The formation manner of the transparent material layer includes, but is not limited to, a preparation technique such as coating or deposition.

In S402, the transparent material layer is patterned. The transparent material layer excluding at least part of the transparent material layer in the light-transmissive hole is removed to form a transparent structure in the light-transmissive hole.

Specifically, referring to FIG. 32, a transparent material layer 302 can be prepared on the side of a driver circuit 200, a light-emitting element 300, and a light-transmissive hole 81 facing away from a substrate 100 by a coating technique. The transparent material layer 302 has fluidity at the time of preparation. Thus, the transparent material layer 302 can effectively fill the light-transmissive hole 81 and cover the light-emitting element 300 and the driver circuit 200. After the transparent material layer 302 is cured, the transparent material layer 302 in a pixel region 70 and part of a light-transmissive hole region 80 is removed by etching the transparent material layer 302 in the pixel region 70 and part of the light-transmissive hole region 80. Only part of the transparent material layer 302 in the light-transmissive hole 81 is retained to form a light-transmissive structure 82 and a second gap 801 located in the light-transmissive hole 81. Thus, the preparation of the transparent structure 82 can also be implemented without a sacrificial layer. This preparation manner facilitates the simplification of the technique preparation process and improves the production efficiency.

In an embodiment, the transparent structure is prepared before the light-shielding structure. In this case, the manner of forming the light-shielding structure at least between the thin-film transistor and the light-emitting element may include filling a light-shielding material in a gap of the transparent structure to form the light-shielding structure. In this manner, the transparent structure can be used as a mask to prepare the light-shielding structure to prevent the light-shielding structure from entering the light-transmissive hole and affecting the light transmittance of the light-transmissive hole. At the same time, when the transparent structure is used as a mask to prepare the light-shielding structure, no additional mask plate is required. The case that the light-shielding structure having fluidity enters the light-transmissive hole, resulting in that the thickness of the light-shielding structure facing the light-transmissive hole is different from that of the light-shielding structure facing away from the light-transmissive hole, which affects the light-shielding effect, does not occur due to the existence of the light-transmitting hole.

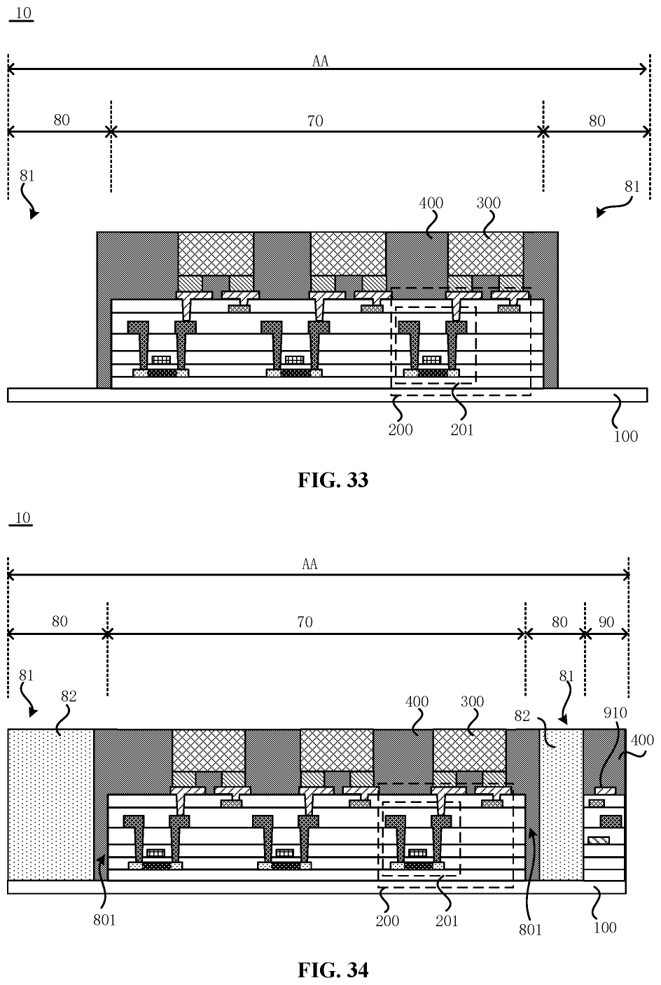

It is to be noted that the preceding only takes the transparent structure disposed in the light-transmissive hole as an example to exemplarily describe the preparation technique and structure of the display panel. In the embodiments of the present invention, the transparent structure in the light-transmissive hole may be removed after the light-shielding structure is formed. In this case, the structure of a display panel is shown in FIG. 33. The manner in which the transparent structure in the light-transmissive hole is removed includes, but is not limited to, a photolithography technique. By removing the transparent structure in the light-transmissive hole after the light-shielding structure is formed, the case that the transparent structure is aged and yellowed for a long time and affects the light transmittance can be avoided. Thus, the position of the light-transmissive hole can have a large light transmittance, thereby improving the display reliability of the display panel.

It is to be understood that in the embodiments of the present invention, a display panel includes at least one light-transmissive hole region. That is, the number of light-transmissive hole regions may be one or more. When multiple light-transmissive hole regions are included, driver circuits in pixel regions located on opposite sides of the light-transmissive hole regions need to be connected by corresponding signal lines. In this case, the display panel may also include a wire region.

In an embodiment, FIG. 34 is a section structure diagram taken along section B-B′ in FIG. 26. Referring to FIG. 26 and FIG. 34, the display region AA also includes a wire region 90. The wire region 90 is located on one side of a light-transmissive hole region 80. The wire region 90 and the pixel region 70 are located on different sides of the light-transmissive hole region 80. The wire region 90 is provided with a signal line 910. The signal line 910 is configured to electrically connect to a driver circuit 200. In the direction perpendicular to the plane in which the substrate 100 is located, the light-shielding structure 400 also covers the signal line 910.

The wire region 90 and the pixel region 70 are located on different sides of the light-transmissive hole region 80. That is, the wire region 90 and the pixel region 70 may be located on two sides adjacent to the light-transmissive hole region 80. At this time, the signal line 910 in the wire region 90 can be electrically connected to driver circuits 200 in pixel regions 70 located on opposite sides of the light-transmissive hole region 80. Thus, the driver circuits 200 in the pixel regions 70 located on opposite sides of the light-transmissive hole region 80 can share the signal line 910, thereby reducing the number of signal lines 910 disposed in the display panel 10. At the same time, since the signal line 910 is used for transmitting an electrical signal, the signal line 910 can be made of a conductive material such as a metal. In this case, the signal line 910 generally has a certain reflection capability. By forming the light-shielding structure 400 on the side of the signal line 910 in the wire region 90 facing away from the substrate 100, light can be blocked from reaching the signal line 910, and the reflection of the light by the signal line 910 can be reduced, thereby improving the display effect.

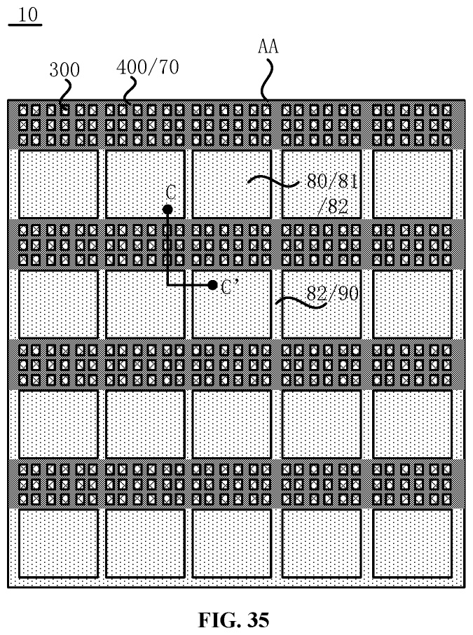

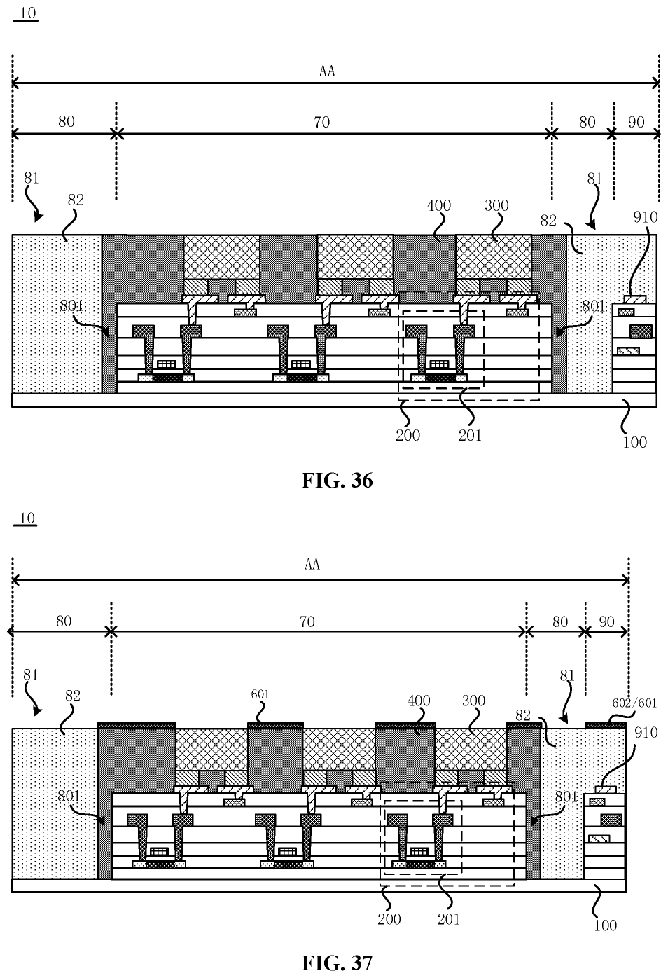

In other optional embodiments, a corresponding light-shielding structure may not be disposed in the wire region. In this case, referring to FIG. 35 and FIG. 36, when the display region AA includes the wire region 90, and the wire region 90 is provided with the signal line 910, the transparent structure 82 may be located on the side of the signal line 910 facing away from the substrate 100. In the direction perpendicular to the plane in which the substrate 100 is located, the transparent structure 82 can cover the signal line 910.

Thus, by forming the transparent structure 82 on the side of the signal line 910 in the wire region 90 facing away from the substrate 100, the step between the wire region 90 and the pixel region 70 can be reduced. Thus, the wire region 90 and the pixel region 70 are relatively flat. At the same time, covering the transparent structure 82 on the side of the signal line 910 facing away from the substrate 100 can increase the light-transmissive property of the display panel 10, thereby facilitating transparent display.

In an embodiment, with continued reference to FIG. 36, the value range of the distance ΔT between the surface of the side of the transparent structure 82 located in the wire region 90 facing away from the substrate 100 and the surface of the side of the light-shielding structure 400 located in the pixel region 70 facing away from the substrate 100 is |ΔT|≤5%*T. T is the thickness of the light-shielding structure 400 located in the pixel region 70 or the transparent structure 82 located in the wire region 90. In this manner, the height difference between the upper surface of the light-shielding structure 400 in the pixel region 70 and the upper surface of the transparent structure 82 in the wire region 90 is limited. Thus, the upper surface of the pixel region 70 and the upper surface of the wire region 90 are flush or have a small difference. This facilitates the simplification of the subsequent technique preparation process and reduces the preparation cost of the display panel 10.

In an embodiment, the wire region may also be provided with a photoresistor structure. The photoresistor structure is located on the side of a light-transmissive structure in the wire region facing away from the substrate. The photoresistor structure is configured to block transmission of at least part of visible light. In this manner, the light entering the wire region can be reduced, and the reflection of the light display by the signal line in the wire region can be reduced, thereby facilitating the improvement of the display contrast of the display panel.

In an example embodiment, FIG. 37 is a section structure diagram of another display panel according to an embodiment of the present invention. Referring to FIG. 37, a photoresist structure 602 may be made of the same material as a color resist structure 601 in a pixel region 70. For example, both the photoresist structure 602 and the color resist structure 601 may be black color resists and prepared in the same process. Thus, the photoresist structure 602 and the color resist structure 601 have the same light-shielding effect, thereby reducing unnecessary reflection in the display panel and improving the display effect of the display panel.

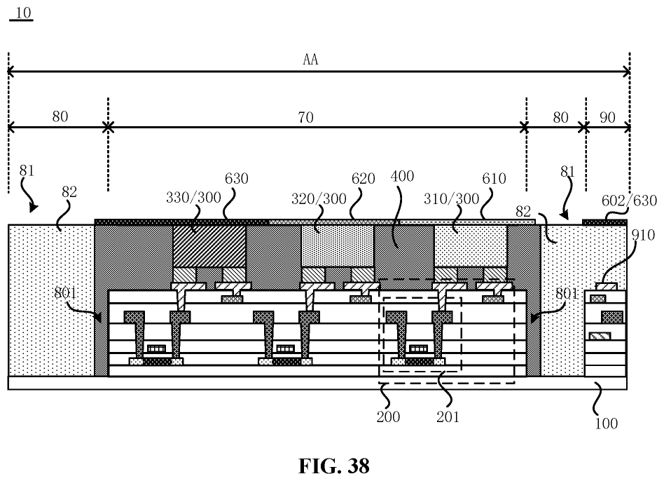

In another example embodiment, FIG. 38 is a section structure diagram of another display panel according to an embodiment of the present invention. Referring to FIG. 38, a photoresist structure 602 may be made of the same material as a second color resist structure 630 in a pixel region 70. For example, both the photoresist structure 602 and the second color resist structure 630 may be blue color resists and prepared in the same process. A blue color resist can transmit blue light while blocking light of other colors. A signal line 910 in a wire region 90 generally has a higher reflection capability for yellow and orange light. Therefore, when the photoresist structure 602 transmits blue light, the signal line in the wire region has a weak capability to reflect this part of the light. In this case, the reflection of the light by the signal line 910 can also be reduced, thereby improving the light-dark contrast of the display panel 10.

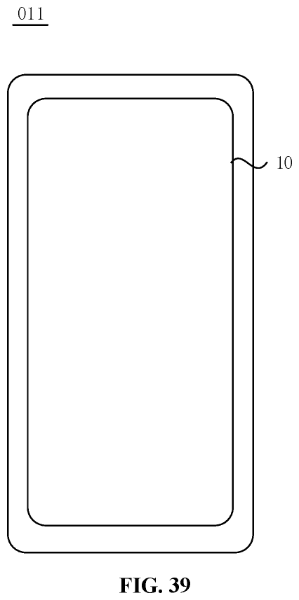

Based on the same inventive concept, the embodiments of the present invention also provide a display device. FIG. 39 is a diagram illustrating the structure of a display device according to an embodiment of the present invention. Referring to FIG. 39, a display device 011 includes the display panel 10 provided in any embodiment of the present invention. Therefore, the display device provided in the embodiments of the present invention has technical features of the display panel provided in the embodiments of the present invention and can achieve the beneficial effects of the display panel provided in the embodiments of the present invention. For the similarities, reference may be made to the preceding description, and details are not described herein.

It is to be understood that the display device 011 provided in the embodiments of the present invention may be the phone shown in FIG. 39, or may be any electronic product with display function, including, but not limited to, the following categories: television, laptop, desktop display, tablet computer, digital camera, smart bracelet, smart glasses, vehicle-mounted display, medical equipment, industrial control equipment, or touch interactive terminal. No special limitations are made thereto in the embodiments of the present invention.

It is to be noted that the preceding are only preferred embodiments of the present invention and the technical principles used therein. It is to be understood by those skilled in the art that the present invention is not limited to the embodiments described herein. Those skilled in the art can make various apparent modifications, adaptations, and substitutions without departing from the scope of the present invention. Therefore, while the present invention has been described in detail through the preceding embodiments, the present invention is not limited to the preceding embodiments and may include more other equivalent embodiments without departing from the concept of the present invention. The scope of the present invention is determined by the scope of the appended claims.

What is claimed is:

1. A display panel, comprising:
a substrate;
a plurality of driver circuits located on a side of the substrate, wherein a driver circuit of the plurality of driver circuits comprises a thin-film transistor;
a plurality of light-emitting elements located on a side of the plurality of driver circuits facing away from the substrate, wherein at least one of the plurality of light-emitting elements is electrically connected to the plurality of driver circuits; and
a light-shielding structure, wherein at least part of the light-shielding structure is at least located between a light-emitting element of the plurality of light-emitting elements and the thin-film transistor, and the light-shielding structure covers at least an active layer of the thin-film transistor in a direction perpendicular to a plane in which the substrate is located.

2. The display panel according to claim 1, wherein the light-shielding structure comprise a first light-shielding portion and a second light-shielding portion;
at least part of the first light-shielding portion is located between the light-emitting element and the thin-film transistor; and the first light-shielding portion overlaps the thin-film transistor in the direction perpendicular to the plane in which the substrate is located; and
the second light-shielding portion is located on a side of the first light-shielding portion facing away from the substrate; and at least part of the second light-shielding portion is located between two adjacent light-emitting elements of the plurality of light-emitting elements.

3. The display panel according to claim 2, wherein a surface of a side of the second light-shielding portion facing the light-emitting element is in contact with a surface of a side of the light-emitting element facing the second light-shielding portion.

4. The display panel according to claim 3, wherein a surface of a side of at least part of the second light-shielding portion facing away from the substrate is a first surface; and a surface of a side of at least one of the plurality of light-emitting elements facing away from the substrate is a second surface, wherein first surface and second surface satisfy at least one of:
at least part of the first surface is flush with the second surface, or at least part of the first surface is located on a side of the second surface facing away from the substrate.

5. The display panel according to claim 3, wherein a surface of a side of at least part of the second light-shielding portion facing away from the substrate is a first surface;
a light-emitting element of the plurality of light-emitting elements comprises a first electrode, a second electrode, and a light-emitting layer;
the first electrode is located on a side of the second electrode facing the substrate; and the light-emitting layer is located between the first electrode and the second electrode; and
the first surface is flush with a surface of a side of the light-emitting layer facing the substrate, or the first surface is located on a side of the light-emitting layer facing the substrate.

6. The display panel according to claim 1, further comprising:
bank structures, wherein a bank structure of the bank structures is located on a side of the light-shielding structure facing away from the substrate and located at least between two adjacent light-emitting elements of the plurality of light-emitting elements, wherein
a first gap is between the bank structure and a light-emitting element of the two adjacent light-emitting elements; and in a direction parallel to the plane in which the substrate is located, a value range of a size d1 of the first gap is 0 μm<d1<L0, wherein L0 is a size of the light-emitting element in the direction parallel to the plane in which the substrate is located.

7. The display panel according to claim 6, wherein a surface of a side of the bank structure facing away from the substrate is a third surface; and a surface of a side of a light-emitting element of the plurality of light-emitting elements facing away from the substrate is a second surface, wherein third surfaces and second surfaces satisfy at least one of:
at least one of the third surfaces is flush with the second surface, or at least one of the third surfaces is located on a side of the second surface facing away from the substrate.

8. The display panel according to claim 6, wherein the bank structure comprises a first bank portion and a second bank portion, wherein
the second bank portion is located on a side of the first bank portion facing away from the substrate; and
a size of the second bank portion is less than or equal to a size of the first bank portion in the direction parallel to the plane in which the substrate is located.

9. The display panel according to claim 8, further comprising:
reflection structures, wherein a reflection structure of the reflection structures is located on a surface of a side of the bank structure facing the light-emitting element, wherein
a reflectance of the reflection structure is greater than a reflectance of the bank structure, and the reflectance of the reflection structure is greater than a reflectance of the light-shielding structure.

10. The display panel according to claim 1, further comprising:
bank structures, wherein a bank structure of the bank structures is located on a side of the light-shielding structure facing away from the substrate and located at least between two adjacent light-emitting elements of the plurality of light-emitting elements, wherein
the bank structure comprises a first bank portion and a second bank portion; and the second bank portion is located on a side of the first bank portion facing away from the substrate; and
a first gap is between the bank structure and a light-emitting element of the two adjacent light-emitting elements; and a size of a first gap between the first bank portion and the light-emitting element is greater than or equal to a size of a first gap between the second bank portion and the light-emitting element.

11. The display panel according to claim 6, wherein a material of the bank structure is the same as a material of the light-shielding structure, or a reflectance of the bank structure is greater than a reflectance of the light-shielding structure.

12. The display panel according to claim 1, further comprising an electrode layer located between the plurality of driver circuits and the plurality of light-emitting elements, wherein the electrode layer comprises bonding electrodes and redundant electrodes;
at least one of the plurality of light-emitting elements is electrically connected to the plurality of driver circuits by a respective one of the bonding electrodes,
a surface of a side of the light-shielding structure facing away from the substrate has a concave structure or a concave-convex structure; and
in the direction perpendicular to the plane in which the substrate is located, the light-shielding structure covers a redundant electrode of the redundant electrodes, and the concave structure or the concave-convex structure overlaps the redundant electrode.

13. The display panel according to claim 1, further comprising:
a color resist layer located on at least a side of the plurality of driver circuits facing away from the substrate, wherein the color resist layer comprises a plurality of color resist structures; and
the plurality of light-emitting elements comprise light-emitting elements of a plurality of colors; and in the direction perpendicular to the plane in which the substrate is located, a color resist structure of the plurality of color resist structures overlaps at least a gap between two adjacent light-emitting elements of the plurality of light-emitting elements.

14. The display panel according to claim 13, wherein the light-emitting elements of a plurality of colors comprise a red light-emitting element, a blue light-emitting element, and a green light-emitting element; and
the plurality of color resist structures comprise a first color resist structure, a second color resist structure, and a third color resist structure; and in the direction perpendicular to the plane in which the substrate is located, the first color resist structure overlaps the red light-emitting element, the second color resist structure overlaps the blue light-emitting element, and the third color resist structure overlaps the green light-emitting element, wherein
the first color resist structure comprises a red color resist or a yellow color resist, the second color resist structure comprises a blue color resist, and the third color resist structure comprises a green color resist or a yellow color resist.

15. The display panel according to claim 14, further comprising:
a plurality of first signal lines located between the substrate and the plurality of light-emitting elements, wherein a first signal line of the plurality of first signal lines is electrically connected to at least one of the plurality of light-emitting elements or one of the plurality of driver circuits; and in the direction perpendicular to the plane in which the substrate is located, at least part of the plurality of first signal lines do not overlap the plurality of light-emitting elements, and the second color resist structure covers the at least part of the plurality of first signal lines that do not overlap the plurality of light-emitting elements.

16. The display panel according to claim 1, wherein a driver circuit of the plurality of driver circuits comprises a first metal structure located on a side of the active layer of the thin-film transistor facing away from the substrate; and
at least part of the light-shielding structure and the first metal structure are disposed in a same layer.

17. The display panel according to claim 16, wherein the light-shielding structure disposed in the same layer with the first metal structure is a first light-shielding structure; and
the light-shielding structure further comprises a second light-shielding structure; the second light-shielding structure is located on a side of the first light-shielding structure facing away from the substrate; and in the direction perpendicular to the plane in which the substrate is located, the second light-shielding structure covers the first light-shielding structure,
wherein a reflectance of the second light-shielding structure is less than a reflectance of the first light-shielding structure.

18. The display panel according to claim 1, wherein a value range of a thickness T1 of the light-shielding structure in the direction perpendicular to the plane in which the substrate is located is T1≥1/OD, wherein OD denotes an optical density value of the light-shielding structure, or an optical density (OD) value of the light-shielding structure satisfies OD≥1.0.

19. The display panel according to claim 1, comprising a display region, wherein the display region comprises at least one light-transmissive hole region and a pixel region located on at least one side of the at least one light-transmissive hole region,
wherein the plurality of light-emitting elements and the plurality of driver circuits are both located in the pixel region; the at least one light-transmissive hole region is provided with light-transmissive holes; the light-transmissive holes penetrate through at least part of film layers of the plurality of driver circuits; and at least part of the light-transmissive holes are provided with a transparent structure.

20. The display panel according to claim 20, wherein a surface of a side of the transparent structure facing the pixel region is in contact with the light-shielding structure.

21. The display panel according to claim 19, wherein a second gap is between the transparent structure and the pixel region,
wherein the light-shielding structure is further located in the second gap.

22. The display panel according to claim 21, wherein a value range of a size d2 of the second gap is 0.5 μm≤d2≤15 μm.

23. The display panel according to claim 19, wherein the display region further comprises a wire region; the wire region is located on a side of the at least one light-transmissive hole region, and the wire region and the pixel region are located on different sides of the light-transmissive holes; the wire region is provided with a signal line; and the signal line is configured to electrically connect to the plurality of driver circuits;
in the direction perpendicular to the plane in which the substrate is located, the light-shielding structure further covers the signal line, or
the transparent structure is further located on a side of the signal line facing away from the substrate; and in the direction perpendicular to the plane in which the substrate is located, the transparent structure further covers the signal line.

24. The display panel according to claim 23, wherein a value range of a distance ΔT between a surface of a side of the transparent structure located in the wire region facing away from the substrate and a surface of a side of the light-shielding structure located in the pixel region facing away from the substrate is |ΔT|≤5%*T, wherein T denotes a thickness of the light-shielding structure located in the pixel region or a thickness of the transparent structure located in the wire region.

25. The display panel according to claim 23, wherein the wire region is further provided with a photoresistor structure, wherein the photoresistor structure is located on a side of a light-transmissive structure in the wire region facing away from the substrate, and
the photoresistor structure is configured to block transmission of at least part of visible light.

26. The display panel according to claim 1, wherein the light-shielding structure comprises a black photoresist or a titanium dioxide-doped photoresist.

27. A method for preparing a display panel, comprising:
providing a substrate;
forming a driver circuit on a side of the substrate, wherein the driver circuit comprises a thin-film transistor;
disposing a light-emitting element on a side of the driver circuit, wherein the light-emitting element is electrically connected to the driver circuit; and
forming a light-shielding structure at least between the thin-film transistor and the light-emitting element.

28. The method for preparing a display panel according to claim 27, wherein forming the light-shielding structure at least between the thin-film transistor and the light-emitting element comprises:
forming a light-shielding material layer covering the light-emitting element and the driver circuit; and
patterning the light-shielding material layer to remove at least a light-shielding material layer located on a side of the light-emitting element facing away from the substrate to form a first light-shielding portion of the light-shielding structure and a second light-shielding portion of the light-shielding structure, wherein the first light-shielding portion is located between the light-emitting element and the thin-film transistor; and the second light-shielding portion is located on a side of the first light-shielding portion facing away from the substrate, and the second light-shielding portion is located between two adjacent light-emitting elements.

29. The method for preparing a display panel according to claim 28, wherein the light-shielding material layer comprises a positive photoresist; and
patterning the light-shielding material layer comprises:
patterning the light-shielding material layer by using a photolithography technique.

30. The method for preparing a display panel according to claim 27, wherein the display panel comprises a display region; the display region comprises a light-transmissive hole region and a pixel region located on one side of the light-transmissive hole region; the driver circuit and the light-emitting element are both disposed in the pixel region; and the light-transmissive hole region is provided with a light-transmissive hole penetrating through at least part of film layers of the driver circuit; and
forming the light-shielding structure at least between the thin-film transistor and the light-emitting element further comprises:
forming a sacrificial layer covering the driver circuit, the light-emitting element, and the light-transmissive hole;
patterning the sacrificial layer to remove at least part of the sacrificial layer located in the light-transmissive hole;
using the sacrificial layer as a mask to form a transparent structure in the light-transmissive hole; and
removing the sacrificial layer after the transparent structure is formed.

31. The method for preparing a display panel according to claim 27, wherein the display panel comprises a display region; the display region comprises a light-transmissive hole region and a pixel region located on one side of the light-transmissive hole region; the driver circuit and the light-emitting element are both disposed in the pixel region; and the light-transmissive hole region is provided with a light-transmissive hole penetrating through at least part of film layers of the driver circuit; and
forming the light-shielding structure at least between the thin-film transistor and the light-emitting element further comprises:
forming a transparent material layer covering the driver circuit, the light-emitting element, and the light-transmissive hole; and
patterning the transparent material layer, and removing a transparent material layer excluding at least part of the transparent material layer in the light-transmissive hole to form a transparent structure in the light-transmissive hole.

32. The method for preparing a display panel according to claim 30, wherein forming the light-shielding structure at least between the thin-film transistor and the light-emitting element comprises:
filling a light-shielding material in a gap of the transparent structure to form the light-shielding structure.

33. The method for preparing a display panel according to claim 30, further comprising:
removing the transparent structure in the light-transmissive hole after the light-shielding structure is formed.

34. A display device, comprising a display panel,
wherein the display panel comprises:
a substrate;
a plurality of driver circuits located on a side of the substrate, wherein a driver circuit of the plurality of driver circuits comprises a thin-film transistor;
a plurality of light-emitting elements located on a side of the plurality of driver circuits facing away from the substrate, wherein at least one of the plurality of light-emitting elements is electrically connected to the plurality of driver circuits; and
a light-shielding structure, wherein at least part of the light-shielding structure is at least located between a light-emitting element of the plurality of light-emitting elements and the thin-film transistor, and the light-shielding structure covers at least an active layer of the thin-film transistor in a direction perpendicular to a plane in which the substrate is located.
